(19) United States
(12) Patent Application Publication
(10) Pub. No.: US 2026/0322405 A1
(43) Pub. Date: Oct. 15, 2026

(54) METHODS, APPARATUS, AND SYSTEM FOR PARITY-CHECK POLAR CODING

(71) Applicant: Huawei Technologies Co., Ltd., Shenzhen (CN)

(72) Inventors: Huazi Zhang, Zhejiang (CN); Jianglei Ma, Ottawa (CA); Wen Tong, Ottawa (CA)

(21) Appl. No.: 19/706,979

(22) Filed: Jun. 12, 2026

Related U.S. Application Data
(63) Continuation of application No. PCT/CN2024/078295, filed on Feb. 23, 2024.
(60) Provisional application No. 63/610,605, filed on Dec. 15, 2023.

(51) Int. Cl. H03M 13/15

(52) U.S. Cl. CPC H03M 13/15

(57) ABSTRACT

A parity-check encoded vector is generated based on a set of information bit positions and a set of one or more parity-check bit positions. For a first position in the parity-check encoded vector belonging to the set of information bit positions, an information bit is assigned to the first position, a bit value of the information bit is inputted to an array of elements and the array of elements is cyclic shifted by one in a shift direction. For a second position in the parity-check encoded vector belonging to the set of one or more parity-check bit positions, a bit value of a parity-check bit is outputted from the array of elements and assigned to the second position, and the array of elements is cyclic shifted by one in the shift direction. The array of elements has five or more elements. A parity-check polar codeword is generated accordingly.

### CROSS-REFERENCE TO RELATED APPLICATIONS

This application is a continuation of International Application No. PCT/CN2024/078295, filed on Feb. 23, 2024, which claims the benefit of U.S. provisional patent application No. 63/610,605, entitled “METHODS, APPARATUS, AND SYSTEM FOR PARITY-CHECK POLAR CODING”, filed Dec. 15, 2023. The disclosures of the aforementioned applications are hereby incorporated by reference in their entireties.

### TECHNICAL FIELD

The present disclosure relates to wireless communications, in particular methods, apparatuses and systems for parity-check (PC) polar coding.

### BACKGROUND

In wireless communications, channel quality is constantly changing due to the fading effects at both fast and slow scale. Accordingly, channel coding has always been designed to adapt to the channel states. Modulation coding scheme (MCS) adaptation is a powerful method to combat varying channel states, in which the modulation order and code length and coding rate can be changed in real time. Therefore, it requires that a channel coding scheme can flexibly change the code length and code rate in a fine-grained way, and at the same time achieve good error correction performance in all possible configurations. This fine-grained flexibility of channel codes is one of the most challenging problems for engineers in this domain.

At the same time, the complexity of both encoding and decoding algorithms need to be sufficiently low. In hardware, complexity can be evaluated through measuring chip area and energy efficiency. They are related to algorithmic complexity, but are more closely related to hardware cost and battery life. Therefore, there exists a desire to reduce implementation complexity when designing coding schemes.

Future communication systems, such as so-called sixth-generation (6G) systems, may aim to support several challenging scenarios, including for example immersive communication, massive communication, and hyper reliable and low-latency communication. The KPIs that are related to channel coding include coding gain, reliability, throughput, latency and their tradeoffs. For example, the throughput target of 6G may reach above 1 Tbps, and the energy efficiency target may decrease to 1 pJ/bit. Meanwhile, a coding scheme supporting flexible rate matching and IR-HARQ schemes is also beneficial. Accordingly, it is desirable yet challenging to design a code ensemble to fulfill all these KPIs and capabilities.

### SUMMARY

In various examples, the present disclosure describes methods, systems and apparatuses for PC polar coding. In examples disclosed herein, methods to generate PC bits for polar coding are described, including methods that use a cyclic shift operation to generate PC bits for polar coding. The cyclic shift operation may be implemented using any suitable hardware and/or software, such as using a cyclic shift register or using a logic-based implementation. Examples of the present disclosure may provide technical advantages in that PC polar coding can be supported for a wider range of code lengths and rates (which may be used to realize performance gains), with more stable performance (e.g., lower error rate). Methods for generating PC bits, as disclosed herein, may be defined or described in a relatively simple manner, which may be beneficial for standardization.

Examples of the present disclosure may enable PC polar coding in which PC encoding is performed using a cyclic shift operation on an array of elements that is at least length five or greater. The cyclic shift operation may be performed on an array of elements of length five or greater (e.g., using a cyclic shift register of length five or greater). Additionally or alternatively, bit values of multiple elements may be combined into another element in the array (e.g., using interconnections in a cyclic shift register). The use of a longer array of elements and/or combination (e.g., XOR) of bit values in the array of elements may enable greater flexibility and variation in how PC bits are generated from information bits, compared to some approaches that generate PC bits from a short-length cyclic shift operation without combination of bit values. For example, approaches that use a cyclic shift register of length five and without any interconnections may not be suitable for generating PC bits for longer codewords (e.g., the resulting codeword may have poor performance or poor stability). Using examples of the present disclosure, longer PC polar codewords (e.g., codewords longer than 20 bits in length) may be generated that exhibit more stable performance (e.g., lower error rate) compared to other approaches that use a cyclic shift register of length five or shorter and/or that do not use combination of bit values for generating PC bits. For example, the use of a longer array and/or combination of bit values in generating PC bits may enable generation of PC polar codewords having longer length, better code weight and larger minimum distance between codewords, among other possible technical advantages.

Methods in accordance with embodiments of the present disclosure may include one or more of the following features: cyclic shift based PC encoding method, for example using a shift register (e.g., having various feedforward and/or feedback structure; clockwise or counter-clockwise shift direction; various input position to the registers; various output positions from the registers); bit assignment method (e.g., all parity bits assignment; systematic bits and parity bits assignment; joint PC encoding and bit assignment).

Some embodiments of the present disclosure include one or more of these features, which can be separately adopted, or work together as a complete solution.

Additional details of the disclosed examples and technical advantages thereof will be described further below.

In an example aspect, the present disclosure describes a method for generating a codeword, the method including: generating a parity-check encoded vector based on a set of information bit positions and a set of one or more parity-check bit positions, wherein: for a first position in the parity-check encoded vector belonging to the set of information bit positions: an information bit from a bit vector of information bits is assigned to the first position, a bit value of the information bit is inputted to an array of elements and the array of elements is cyclic shifted by one in a shift direction; for a second position in the parity-check encoded vector belonging to the set of one or more parity-check bit positions: a bit value of a parity-check bit is outputted from the array of elements and assigned to the second position, and the array of elements is cyclic shifted by one in the shift direction; and the array of elements has five or more elements. The method also includes: generating a parity-check polar codeword by applying a polar code to the parity-check encoded vector; and outputting the parity-check polar codeword.

In an example of the preceding example aspect, at least one element in the array of elements may be based on a combination of two or more other elements in the array of elements.

In an example of the preceding example aspect, the combination may be a feedback combination in which the two or more other elements that are combined include one other element that is downstream of the at least one element in the shift direction.

In an example of a preceding example aspect, the combination may be a feedforward combination in which the two or more other elements that are combined are other elements that are upstream of the at least one element in the shift direction.

In an example of a preceding example aspect, the cyclic shift operation and the array of elements may be implemented using a cyclic shift register, and the cyclic shift register may include an interconnection to implement the combination of the two or more other elements.

In an example of the preceding example aspect, the interconnection may be a feedforward interconnection, the feedforward interconnection being a directional interconnection that is in a same direction as the shift direction of the cyclic shift register.

In an example of a preceding example aspect, the interconnection may be a feedback interconnection, the feedback interconnection being a directional interconnection that is opposite in direction to the shift direction of the cyclic shift register.

In an example of any of the preceding example aspects, there may be one or more elements based on respective one or more combinations of other elements, and the one or more combinations may be implemented using a binary vector representation of a polynomial representing the one or more combinations.

In an example of the preceding example aspect, the polynomial may be based on a given rate matching output sequence length and a given information block length.

In an example of any of the preceding example aspects, the bit value of the information bit may be inputted to an element of the array of elements other than a highest indexed element and also other than a lowest indexed element.

In an example of any of the preceding example aspects, the bit value of the parity-check bit may be outputted from an element of the array of elements other than the highest indexed element and also other than the lowest indexed element.

In an example of any of the preceding example aspects, the parity-check encoded vector may be generated based on the set of information bit positions, the set of one or more parity-check bit position and a set of one or more frozen bit positions, and for a third position in the parity-check encoded vector belonging to the set of frozen bit positions, a frozen bit value may be assigned to the third position.

In an example of any of the preceding example aspects, the shift direction may be from a highest index element in the array of elements to a lowest index element in the array of elements.

In an example of some of the preceding example aspects, the shift direction may be from a lowest index element in the array of elements to a highest index element in the array of elements.

In an example of any of the preceding example aspects, all bit positions of the parity-check encoded vector belonging to the set of one or more parity-check bit positions may contain bit values outputted from the array of elements.

In an example of any of the preceding example aspects, the method may include: transmitting the parity-check polar codeword over a communication channel.

In an example of any of the preceding example aspects, the method may include: obtaining the bit vector of information bits.

In another example aspect, the present disclosure describes a method for decoding a codeword, the method including: decoding a parity-check polar codeword, wherein the decoding includes: inputting a bit value of each decoded information bit to an array of elements and cyclic shifting the array of elements by one in a shift direction; and generating one or more parity-check bits by, for each parity-check bit, outputting a bit value of the parity-check bit from the array of elements and cyclic shifting the array of elements by one in the shift direction; wherein the array of elements has five or more elements. The method also includes: outputting the decoded parity-check polar codeword.

In an example of the preceding example aspect, at least one element in the array of elements may be based on a combination of two or more other elements in the array of elements.

In an example of the preceding example aspect, the cyclic shift operation and the array of elements may be implemented using a cyclic shift register, and the cyclic shift register may include an interconnection to implement the combination of the two or more other elements.

In an example of any of the preceding example aspects, the method may include: receiving the parity-check polar codeword.

In another example aspect, the present disclosure describes an apparatus including: a processor; and a memory including instructions that, when executed by the processor, cause the apparatus to perform any of the preceding example aspects of the method.

In another example aspect, the present disclosure describes an apparatus including: an encoding module configured to carry out the steps of any of the preceding example aspects of the method for generating a codeword; and a decoding module configured to carry out the receiving steps of any of the preceding example aspects of the method for decoding a codeword.

In another example aspect, the present disclosure describes a non-transitory computer readable medium having machine-executable instructions stored thereon, wherein the instructions, when executed by a computing apparatus, cause the apparatus to perform any of the preceding example aspects of the method.

In another example aspect, the present disclosure describes a processing module configured to control an apparatus to cause the apparatus to carry out any of the preceding example aspects of the method.

In another example aspect, the present disclosure describes a chip or a chipset comprising a processor configured to execute instructions to cause an apparatus to carry out any of the preceding example aspects of the method.

In another example aspect, the present disclosure describes a computer program characterized in that, when the computer program is run on a computer, the computer is caused to execute any of the preceding example aspects of the method.

### BRIEF DESCRIPTION OF THE DRAWINGS

Reference will now be made, by way of example, to the accompanying drawings which show example embodiments of the present application, and in which:

FIG. 1 is a simplified schematic illustration of a communication system, which may be used to implement examples of the present disclosure;

FIG. 2 is a block diagram illustrating an example of a communication system, which may be used to implement examples of the present disclosure;

FIG. 3 is a block diagram illustrating an example of devices of a communication system, which may be used to implement examples of the present disclosure;

FIG. 4 is a block diagram illustrating example units or modules in a device, which may be used to implement examples of the present disclosure;

FIG. 5 is a trellis graph illustrating an example of a polar code, which may be used to implement examples of the present disclosure;

FIG. 6 is a table illustrating an example interleaver scheme, which may be used to implement examples of the present disclosure;

FIG. 7 illustrates examples of puncturing or shortening using a circular buffer, which may be used to implement examples of the present disclosure;

FIG. 8 illustrates an example set of transmissions with incremental freezing, which may be implemented using examples of the present disclosure;

FIG. 9 illustrates an example implementation of a PC polar coding scheme using a cyclic shift register, which may be implemented using examples of the present disclosure;

FIG. 10 illustrates an example of polar coding in an IR-HARQ scheme, which may be implemented using examples of the present disclosure;

FIG. 11 illustrates an example of polar transformation matrices that may be used for different transmissions in an IR-HARQ scheme, which may be used to implement examples of the present disclosure;

FIG. 12 illustrates an example of an encoding chain, which may be used to implement examples of the present disclosure;

FIG. 13 illustrates an example implementation of a cyclic shift operation with interconnections, in accordance with examples of the present disclosure;

FIGS. 14A-14D illustrate example implementations of various shift operations with various shift directions, in accordance with examples of the present disclosure;

FIGS. 15A-15G illustrate example implementations of various shift operations with various combination of elements, in accordance with examples of the present disclosure;

FIGS. 16A-16F illustrate example implementations of various shift operations with input and output at various elements, in accordance with examples of the present disclosure;

FIGS. 17A-17B illustrate example implementations of various shift operations in which the output is not a direct copy of an input, in accordance with examples of the present disclosure;

FIG. 18 illustrates an example implementation of a shift operation using a cyclic shift register with selection of information bit or PC bit, in accordance with examples of the present disclosure;

FIG. 19-21 show various pseudocode to generate a PC encoded vector to be encoded into a polar codeword, in accordance with examples of the present disclosure;

FIG. 22 illustrates an example implementation of a cyclic shift operation using a cyclic shift register having interconnections represented by a binary vector, in accordance with examples of the present disclosure;

FIG. 23 shows pseudocode to generate a PC encoded vector to be encoded into a polar codeword, using a cyclic shift operation, in accordance with examples of the present disclosure;

FIG. 24 illustrates an example implementation of the cyclic shift operation in the pseudocode of FIG. 23, using a cyclic shift register, in accordance with examples of the present disclosure;

FIG. 25 shows a table containing example polar parameters for generating parity check bits, in accordance with examples of the present disclosure;

FIG. 26A-26B are block diagrams illustrating example units or modules in a device, which may be used to implement examples of the present disclosure;

FIG. 27 is a flowchart illustrating an example method for generating a PC polar codeword, in accordance with examples of the present disclosure; and

FIG. 28 is a flowchart illustrating an example method for decoding a PC polar codeword, in accordance with examples of the present disclosure.

Similar reference numerals may have been used in different figures to denote similar components.

### DETAILED DESCRIPTION OF THE ILLUSTRATIVE EMBODIMENTS

In various examples, the present disclosure describes methods, apparatuses, and systems for PC polar coding. Examples of the present disclosure may enable methods of PC polar coding using a cyclic shift operation to generate PC bits. Examples of the present disclosure may support stable performance for a wider range of code lengths and rates for PC polar coding, which may help to achieve performance gains.

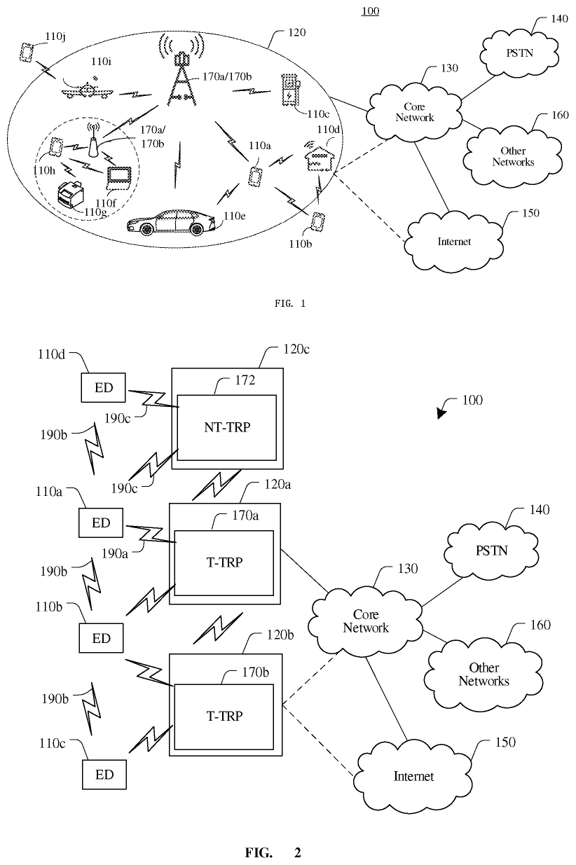

To assist in understanding the present disclosure, reference is first made to FIG. 1.

Referring to FIG. 1, as an illustrative example without limitation, a simplified schematic illustration of a communication system is provided. The communication system 100 comprises a radio access network 120. The radio access network 120 may be a next generation (e.g. sixth generation (6G) or later) radio access network, or a legacy (e.g. 5G, 4G, 3G or 2G) radio access network. One or more communication electronic devices (ED) 110a, 110b, 110c, 110d, 110e, 110f, 110g, 110h, 110i, 110j (generically referred to as 110) may be interconnected to one another or connected to one or more network nodes (170a, 170b, generically referred to as 170) in the radio access network 120. A core network 130 may be a part of the communication system and may be dependent or independent of the radio access technology used in the communication system 100. Also the communication system 100 comprises a public switched telephone network (PSTN) 140, the internet 150, and other networks 160.

FIG. 2 illustrates an example communication system 100. In general, the communication system 100 enables multiple wireless or wired elements to communicate data and other content. The purpose of the communication system 100 may be to provide content, such as voice, data, video, and/or text, via broadcast, multicast, groupcast, unicast, etc. The communication system 100 may operate by sharing resources, such as carrier spectrum bandwidth, between its constituent elements. The communication system 100 may include a terrestrial communication system and/or a non-terrestrial communication system. The communication system 100 may provide a wide range of communication services and applications (such as earth monitoring, remote sensing, passive sensing and positioning, navigation and tracking, autonomous delivery and mobility, etc.). The communication system 100 may provide a high degree of availability and robustness through a joint operation of a terrestrial communication system and a non-terrestrial communication system. For example, integrating a non-terrestrial communication system (or components thereof) into a terrestrial communication system can result in what may be considered a heterogeneous network comprising multiple layers. Compared to conventional communication networks, the heterogeneous network may achieve better overall performance through efficient multi-link joint operation, more flexible functionality sharing, and faster physical layer link switching between terrestrial networks and non-terrestrial networks.

The terrestrial communication system and the non-terrestrial communication system could be considered sub-systems of the communication system. In the example shown in FIG. 2, the communication system 100 includes electronic devices (ED) 110a, 110b, 110c, 110d (generically referred to as ED 110), radio access networks (RANs) 120a, 120b, a non-terrestrial communication network 120c, a core network 130, a public switched telephone network (PSTN) 140, the Internet 150, and other networks 160. The RANs 120a, 120b include respective base stations (BSs) 170a, 170b, which may be generically referred to as terrestrial transmit and receive points (T-TRPs) 170a, 170b. The non-terrestrial communication network 120c includes an access node 172, which may be generically referred to as a non-terrestrial transmit and receive point (NT-TRP) 172.

Any ED 110 may be alternatively or additionally configured to interface, access, or communicate with any T-TRP 170a,170b and NT-TRP 172, the Internet 150, the core network 130, the PSTN 140, the other networks 160, or any combination of the preceding. In some examples, ED 110a may communicate an uplink and/or downlink transmission over a terrestrial air interface 190a with T-TRP 170a. In some examples, the EDs 110a, 110b, 110c, and 110d may also communicate directly with one another via one or more sidelink air interfaces 190b. In some examples, ED 110d may communicate an uplink and/or downlink transmission over a non-terrestrial air interface 190c with NT-TRP 172.

The air interfaces 190a and 190b may use similar communication technology, such as any suitable radio access technology. For example, the communication system 100 may implement one or more channel access methods, such as code division multiple access (CDMA), space division multiple access (SDMA), time division multiple access (TDMA), frequency division multiple access (FDMA), orthogonal FDMA (OFDMA), or single-carrier FDMA (SC-FDMA, also known as discrete Fourier transform spread OFDMA, DFT-s-OFDMA) in the air interfaces 190a and 190b. The air interfaces 190a and 190b may utilize other higher dimension signal spaces, which may involve a combination of orthogonal and/or non-orthogonal dimensions.

The non-terrestrial air interface 190c can enable communication between the ED 110d and one or multiple NT-TRPs 172 via a wireless link or simply a link. For some examples, the link is a dedicated connection for unicast transmission, a connection for broadcast transmission, or a connection between a group of EDs 110 and one or multiple NT-TRPs 172 for multicast transmission.

The RANs 120a and 120b are in communication with the core network 130 to provide the EDs 110a 110b, and 110c with various services such as voice, data, and other services. The RANs 120a and 120b and/or the core network 130 may be in direct or indirect communication with one or more other RANs (not shown), which may or may not be directly served by core network 130, and may or may not employ the same radio access technology as RAN 120a, RAN 120b or both. The core network 130 may also serve as a gateway access between (i) the RANs 120a and 120b or EDs 110a 110b, and 110c or both, and (ii) other networks (such as the PSTN 140, the Internet 150, and the other networks 160). In addition, some or all of the EDs 110a 110b, and 110c may include functionality for communicating with different wireless networks over different wireless links using different wireless technologies and/or protocols. Instead of wireless communication (or in addition thereto), the EDs 110a 110b, and 110c may communicate via wired communication channels to a service provider or switch (not shown), and to the Internet 150. PSTN 140 may include circuit switched telephone networks for providing plain old telephone service (POTS). Internet 150 may include a network of computers and subnets (intranets) or both, and incorporate protocols, such as Internet Protocol (IP), Transmission Control Protocol (TCP), User Datagram Protocol (UDP). EDs 110a 110b, and 110c may be multimode devices capable of operation according to multiple radio access technologies, and incorporate multiple transceivers necessary to support such.

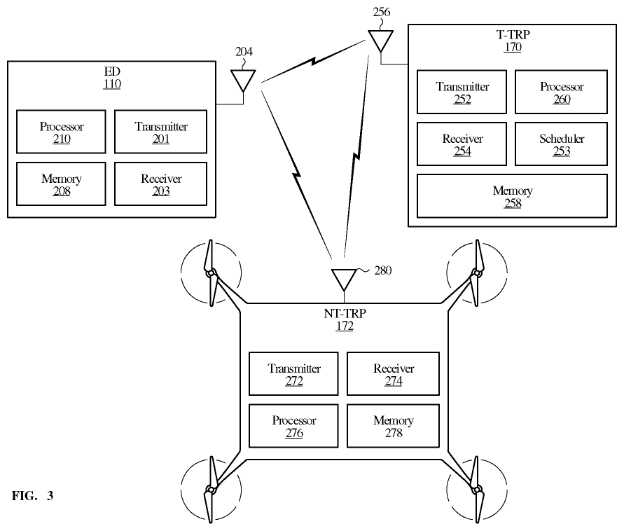

FIG. 3 illustrates another example of an ED 110 and a base station 170a, 170b and/or 170c. The ED 110 is used to connect persons, objects, machines, etc. The ED 110 may be widely used in various scenarios including, for example, cellular communications, device-to-device (D2D), vehicle to everything (V2X), peer-to-peer (P2P), machine-to-machine (M2M), machine-type communications (MTC), internet of things (IoT), virtual reality (VR), augmented reality (AR), mixed reality (MR), metaverse, digital twin, industrial control, self-driving, remote medical, smart grid, smart furniture, smart office, smart wearable, smart transportation, smart city, drones, robots, remote sensing, passive sensing, positioning, navigation and tracking, autonomous delivery and mobility, etc.

Each ED 110 represents any suitable end user device for wireless operation and may include such devices (or may be referred to) as a user equipment/device (UE), a wireless transmit/receive unit (WTRU), a mobile station, a fixed or mobile subscriber unit, a cellular telephone, a station (STA), a machine type communication (MTC) device, a personal digital assistant (PDA), a smartphone, a laptop, a computer, a tablet, a wireless sensor, a consumer electronics device, a smart book, a vehicle, a car, a truck, a bus, a train, or an IoT device, wearable devices (such as a watch, a pair of glasses, head mounted equipment, etc.), an industrial device, or an apparatus in (e.g. communication module, modem, or chip) or comprising the forgoing devices, among other possibilities. Future generation EDs 110 may be referred to using other terms. The base station 170a and 170b is a T-TRP and will hereafter be referred to as T-TRP 170. Also shown in FIG. 3, a NT-TRP will hereafter be referred to as NT-TRP 172. Each ED 110 connected to T-TRP 170 and/or NT-TRP 172 can be dynamically or semi-statically turned-on (i.e., established, activated, or enabled), turned-off (i.e., released, deactivated, or disabled) and/or configured in response to one of more of: connection availability and connection necessity.

The ED 110 includes a transmitter 201 and a receiver 203 coupled to one or more antennas 204. Only one antenna 204 is illustrated to avoid congestion in the drawing. One, some, or all of the antennas 204 may alternatively be panels. The transmitter 201 and the receiver 203 may be integrated, e.g. as a transceiver. The transceiver is configured to modulate data or other content for transmission by at least one antenna 204 or network interface controller (NIC). The transceiver is also configured to demodulate data or other content received by the at least one antenna 204. Each transceiver includes any suitable structure for generating signals for wireless or wired transmission and/or processing signals received wirelessly or by wire. Each antenna 204 includes any suitable structure for transmitting and/or receiving wireless or wired signals.

The ED 110 includes at least one memory 208. The memory 208 stores instructions and data used, generated, or collected by the ED 110. For example, the memory 208 could store software instructions or modules configured to implement some or all of the functionality and/or embodiments described herein and that are executed by one or more processing unit(s) (e.g., a processor 210). Each memory 208 includes any suitable volatile and/or non-volatile storage and retrieval device(s). Any suitable type of memory may be used, such as random access memory (RAM), read only memory (ROM), hard disk, optical disc, subscriber identity module (SIM) card, memory stick, secure digital (SD) memory card, on-processor cache, and the like.

The ED 110 may further include one or more input/output devices (not shown) or interfaces (such as a wired interface to the Internet 150 in FIG. 1). The input/output devices or interfaces permit interaction with a user or other devices in the network. Each input/output device or interface includes any suitable structure for providing information to or receiving information from a user, and/or for network interface communications. Suitable structures include, for example, a speaker, microphone, keypad, keyboard, display, touch screen, etc.

The ED 110 includes the processor 210 for performing operations including those operations related to preparing a transmission for uplink transmission to the NT-TRP 172 and/or the T-TRP 170; those operations related to processing downlink transmissions received from the NT-TRP 172 and/or the T-TRP 170; and those operations related to processing sidelink transmission to and from another ED 110. Processing operations related to preparing a transmission for uplink transmission may include operations such as encoding, modulating, transmit beamforming, and generating symbols for transmission. Processing operations related to processing downlink transmissions may include operations such as receive beamforming, demodulating and decoding received symbols. Depending upon the embodiment, a downlink transmission may be received by the receiver 203, possibly using receive beamforming, and the processor 210 may extract signaling from the downlink transmission (e.g. by detecting and/or decoding the signaling). An example of signaling may be a reference signal transmitted by the NT-TRP 172 and/or by the T-TRP 170. In some embodiments, the processor 210 implements the transmit beamforming and/or the receive beamforming based on the indication of beam direction, e.g. beam angle information (BAI), received from the T-TRP 170. In some embodiments, the processor 210 may perform operations relating to network access (e.g. initial access) and/or downlink synchronization, such as operations relating to detecting a synchronization sequence, decoding and obtaining the system information, etc. In some embodiments, the processor 210 may perform channel estimation, e.g. using a reference signal received from the NT-TRP 172 and/or from the T-TRP 170.

Although not illustrated, the processor 210 may form part of the transmitter 201 and/or part of the receiver 203. Although not illustrated, the memory 208 may form part of the processor 210.

The processor 210, the processing components of the transmitter 201, and the processing components of the receiver 203 may each be implemented by the same or different one or more processors that are configured to execute instructions stored in a memory (e.g. in the memory 208). Alternatively, some or all of the processor 210, the processing components of the transmitter 201, and the processing components of the receiver 203 may each be implemented using dedicated circuitry, such as a programmed field-programmable gate array (FPGA), an application-specific integrated circuit (ASIC), or a hardware accelerator such as a graphics processing unit (GPU) or an artificial intelligence (AI) accelerator.

The T-TRP 170 may be known by other names in some implementations, such as a base station, a base transceiver station (BTS), a radio base station, a network node, a network device, a device on the network side, a transmit/receive node, a Node B, an evolved NodeB (eNodeB or eNB), a Home eNodeB, a next Generation NodeB (gNB), a transmission point (TP), a site controller, an access point (AP), a wireless router, a relay station, a terrestrial node, a terrestrial network device, a terrestrial base station, a base band unit (BBU), a remote radio unit (RRU), an active antenna unit (AAU), a remote radio head (RRH), a central unit (CU), a distributed unit (DU), a positioning node, among other possibilities. The T-TRP 170 may be a macro BS, a pico BS, a relay node, a donor node, or the like, or combinations thereof. The T-TRP 170 may refer to the forgoing devices or refer to apparatus (e.g. a communication module, a modem, or a chip) in the forgoing devices.

In some embodiments, the parts of the T-TRP 170 may be distributed. For example, some of the modules of the T-TRP 170 may be located remote from the equipment that houses the antennas 256 for the T-TRP 170, and may be coupled to the equipment that houses the antennas 256 over a communication link (not shown) sometimes known as front haul, such as common public radio interface (CPRI). Therefore, in some embodiments, the term T-TRP 170 may also refer to modules on the network side that perform processing operations, such as determining the location of the ED 110, resource allocation (scheduling), message generation, and encoding/decoding, and that are not necessarily part of the equipment that houses the antennas 256 of the T-TRP 170. The modules may also be coupled to other T-TRPs. In some embodiments, the T-TRP 170 may actually be a plurality of T-TRPs that are operating together to serve the ED 110, e.g. through the use of coordinated multipoint transmissions.

The T-TRP 170 includes at least one transmitter 252 and at least one receiver 254 coupled to one or more antennas 256. Only one antenna 256 is illustrated to avoid congestion in the drawing. One, some, or all of the antennas 256 may alternatively be panels. The transmitter 252 and the receiver 254 may be integrated as a transceiver. The T-TRP 170 further includes a processor 260 for performing operations including those related to: preparing a transmission for downlink transmission to the ED 110, processing an uplink transmission received from the ED 110, preparing a transmission for backhaul transmission to the NT-TRP 172, and processing a transmission received over backhaul from the NT-TRP 172. Processing operations related to preparing a transmission for downlink or backhaul transmission may include operations such as encoding, modulating, precoding (e.g. multiple input multiple output (MIMO) precoding), transmit beamforming, and generating symbols for transmission. Processing operations related to processing received transmissions in the uplink or over backhaul may include operations such as receive beamforming, demodulating received symbols, and decoding received symbols. The processor 260 may also perform operations relating to network access (e.g. initial access) and/or downlink synchronization, such as generating the content of synchronization signal blocks (SSBs), generating the system information, etc. In some embodiments, the processor 260 also generates an indication of beam direction, e.g. BAI, which may be scheduled for transmission by a scheduler 253. The processor 260 performs other network-side processing operations described herein, such as determining the location of the ED 110, determining where to deploy the NT-TRP 172, etc. In some embodiments, the processor 260 may generate signaling, e.g. to configure one or more parameters of the ED 110 and/or one or more parameters of the NT-TRP 172. Any signaling generated by the processor 260 is sent by the transmitter 252. Note that “signaling”, as used herein, may alternatively be called control signaling. Signaling may be transmitted in a physical layer control channel, e.g. a physical downlink control channel (PDCCH), in which case the signaling may be known as dynamic signaling. Signaling transmitted in a downlink physical layer control channel may be known as Downlink Control Information (DCI). Signaling transmitted in an uplink physical layer control channel may be known as Uplink Control Information (UCI). Signaling transmitted in a sidelink physical layer control channel may be known as Sidelink Control Information (SCI). Signaling may be included in a higher-layer (e.g., higher than physical layer) packet transmitted in a physical layer data channel, e.g. in a physical downlink shared channel (PDSCH), in which case the signaling may be known as higher-layer signaling, static signaling, or semi-static signaling. Higher-layer signaling may also refer to Radio Resource Control (RRC) protocol signaling or Media Access Control-Control Element (MAC-CE) signaling.

The scheduler 253 may be coupled to the processor 260. The scheduler 253 may be included within or operated separately from the T-TRP 170. The scheduler 253 may schedule uplink, downlink, sidelink, and/or backhaul transmissions, including issuing scheduling grants and/or configuring scheduling-free (e.g., “configured grant”) resources. The T-TRP 170 further includes a memory 258 for storing information and data. The memory 258 stores instructions and data used, generated, or collected by the T-TRP 170. For example, the memory 258 could store software instructions or modules configured to implement some or all of the functionality and/or embodiments described herein and that are executed by the processor 260.

Although not illustrated, the processor 260 may form part of the transmitter 252 and/or part of the receiver 254. Also, although not illustrated, the processor 260 may implement the scheduler 253. Although not illustrated, the memory 258 may form part of the processor 260.

The processor 260, the scheduler 253, the processing components of the transmitter 252, and the processing components of the receiver 254 may each be implemented by the same or different one or more processors that are configured to execute instructions stored in a memory, e.g. in the memory 258. Alternatively, some or all of the processor 260, the scheduler 253, the processing components of the transmitter 252, and the processing components of the receiver 254 may be implemented using dedicated circuitry, such as a programmed FPGA, a hardware accelerator (e.g., a GPU or AI accelerator), or an ASIC.

Although the NT-TRP 172 is illustrated as a drone only as an example, the NT-TRP 172 may be implemented in any suitable non-terrestrial form, such as satellites and high altitude platforms, including international mobile telecommunication base stations and unmanned aerial vehicles, for example. Also, the NT-TRP 172 may be known by other names in some implementations, such as a non-terrestrial node, a non-terrestrial network device, or a non-terrestrial base station. The NT-TRP 172 includes a transmitter 272 and a receiver 274 coupled to one or more antennas 280. Only one antenna 280 is illustrated to avoid congestion in the drawing. One, some, or all of the antennas may alternatively be panels. The transmitter 272 and the receiver 274 may be integrated as a transceiver. The NT-TRP 172 further includes a processor 276 for performing operations including those related to: preparing a transmission for downlink transmission to the ED 110, processing an uplink transmission received from the ED 110, preparing a transmission for backhaul transmission to T-TRP 170, and processing a transmission received over backhaul from the T-TRP 170. Processing operations related to preparing a transmission for downlink or backhaul transmission may include operations such as encoding, modulating, precoding (e.g. MIMO precoding), transmit beamforming, and generating symbols for transmission. Processing operations related to processing received transmissions in the uplink or over backhaul may include operations such as receive beamforming, demodulating received symbols, and decoding received symbols. In some embodiments, the processor 276 implements the transmit beamforming and/or receive beamforming based on beam direction information (e.g. BAI) received from the T-TRP 170. In some embodiments, the processor 276 may generate signaling, e.g. to configure one or more parameters of the ED 110. In some embodiments, the NT-TRP 172 implements physical layer processing, but does not implement higher layer functions such as functions at the medium access control (MAC) or radio link control (RLC) layer. As this is only an example, more generally, the NT-TRP 172 may implement higher layer functions in addition to physical layer processing.

The NT-TRP 172 further includes a memory 278 for storing information and data. Although not illustrated, the processor 276 may form part of the transmitter 272 and/or part of the receiver 274. Although not illustrated, the memory 278 may form part of the processor 276.

The processor 276, the processing components of the transmitter 272, and the processing components of the receiver 274 may each be implemented by the same or different one or more processors that are configured to execute instructions stored in a memory, e.g. in the memory 278. Alternatively, some or all of the processor 276, the processing components of the transmitter 272, and the processing components of the receiver 274 may be implemented using dedicated circuitry, such as a programmed FPGA, a hardware accelerator (e.g., a GPU or AI accelerator), or an ASIC. In some embodiments, the NT-TRP 172 may actually be a plurality of NT-TRPs that are operating together to serve the ED 110, e.g. through coordinated multipoint transmissions.

The T-TRP 170, the NT-TRP 172, and/or the ED 110 may include other components, but these have been omitted for the sake of clarity.

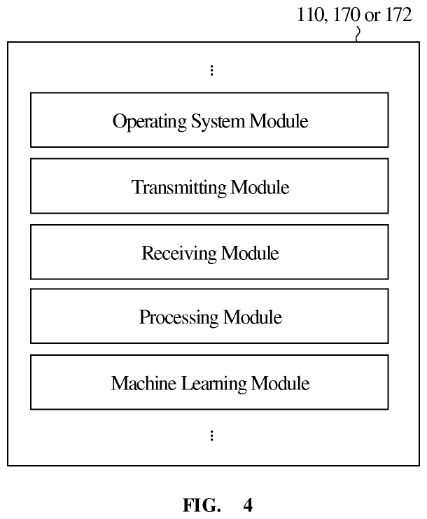

One or more steps of the embodiment methods provided herein may be performed by corresponding units or modules, according to FIG. 4. FIG. 4 illustrates units or modules in a device, such as in the ED 110, in the T-TRP 170, or in the NT-TRP 172. For example, a signal may be transmitted or output by a transmitting unit or by a transmitting module. A signal may be received or input by a receiving unit or by a receiving module. A signal may be processed by a processing unit or a processing module. Other steps may be performed by an artificial intelligence (AI) or machine learning (ML) module. The respective units or modules may be implemented using hardware, one or more components or devices that execute software, or a combination thereof. For instance, one or more of the units or modules may be a circuit such as an integrated circuit. Examples of an integrated circuit includes a programmed FPGA, a GPU, or an ASIC. For instance, one or more of the units or modules may be logical such as a logical function performed by a circuit, by a portion of an integrated circuit, or by software instructions executed by a processor. It will be appreciated that where the modules are implemented using software for execution by a processor for example, the modules may be retrieved by a processor, in whole or part as needed, individually or together for processing, in single or multiple instances, and that the modules themselves may include instructions for further deployment and instantiation.

While not shown, the transmitting module and the receiving module may be part of, or combined into, a transceiver module. A transceiver module may also be known as an interface module, or simply an interface, for inputting and outputting operations.

Additional details regarding the EDs 110, the T-TRP 170, and the NT-TRP 172 are known to those of skill in the art. As such, these details are omitted here.

The channel coding module in communications systems encode K source bits into N code bits to provide error correction capability against adversary channel conditions such as noise and interference. The code rate is R=K/N. In practice, the code rate R is selected according to channel quality.

Polar codes are capacity-achieving codes and thus a great breakthrough in coding theory. As code length approaches infinity, the synthesized channels (also known as subchannels, which are created by or associated with the polar code) become either noiseless or pure noise. The noiseless subchannels are utilized to transport information, and their proportion is proven to achieve the channel capacity defined by Shannon. The above-mentioned channel polarization phenomenon occurs under successive cancellation (SC) or SC-based decoding, which has a relatively low complexity.

Low-density parity-check (LDPC) codes are capacity-approaching codes. LDPC codes may be defined by a PC matrix, which typically has far more zeros than ones—in other words, having low density. By properly designing the positions of the ones in the matrix, the decoding performance can be improved. Although LDPC codes can theoretically be viewed as a type of random code, certain structures, whether conceptual or physical, can facilitate the hardware implementation of LDPC encoders and decoders. A “Quasi-cyclic” (QC) structure is an example structure that may improve performance and/or implementation complexity. A QC-LDPC scheme first defines a smaller base matrix or base graph (BG), and then performs a “lifting” operation that replaces the ones in the base matrix or graph with a cyclic shifted version of an identity matrix.

Rate matching is performed after channel encoding, by either puncturing/shortening or repeating some code bits. The purpose of this operation is to obtain a code bit sequence of desired length for transmission over limited channel resources.

Channel interleaving is applied after channel encoding and rate matching by permuting the code bits. The purpose is to provide stable or superior performance under high-order modulation or in a fading channel.

Hybrid automatic repeat request (HARQ) is a mechanism to provide reliable wireless transmission. It combines forward error correction (FEC) and automatic repeat request (ARQ). In HARQ, the initial transmission is a FEC code word with means (such as CRC bits) to support error detection at the receiver. If a decoding error is detected, the receiver will send back a negative acknowledgment (NACK) signaling to inform the transmitter of the error, and request a retransmission. The retransmitted bits can be directly selected from the initially transmitted bits, or incrementally generated code bits which form a longer code word with the initially transmitted bits. The former approach is called chase-combining HARQ (CC-HARQ) and the latter approach is called incremental-redundancy HARQ (IR-HARQ). Typically, IR-HARQ outperforms CC-HARQ with the additional coding gain from incremental redundancy.

Polar codes belong to the class of linear block codes. For a polar code of length N, its generator matrix is G_{N}, and its encoding process is

$${x}_{1}^{N} = {u}_{1}^{N} {G}_{N} ,$$

where

$${u}_{1}^{N} = [ {u}_{1} , {u}_{2} , … , {u}_{N} ]$$

binary information vector,

$${x}_{1}^{N} = [ {x}_{1} , {x}_{2} , … , {x}_{N} ]$$

is the binary code vector. The N×N binary matrix

$${G}_{N} = {F}_{2}^{⊗ n} ,$$

where

$${F}_{2} = [ \begin{matrix}1 & 0 \\ 1 & 1\end{matrix} ]$$

is the polarization kernal matrix, n=log₂N, and ⊗ is Kronecker product.

Typically, there are K information bits to be encoded into N code bits. Accordingly, the inequality K<N is given to obtain a code rate R=K/N<1. That implies only part of

$${u}_{1}^{N}$$

is used to carry information bits, and the rest are typically called frozen bits. Denote by I the information bit set (or information set), and F the frozen bit set (or frozen set), respectively. Sometimes, there is an additional PC bit set, denoted by P. The frozen bits are known (usually all zeros, but may also be other known values or sequences) before decoding, so they do not carry any payload information. The PC bits are generated from a subset of information bits. Therefore, the PC bits are known once the associated information bits are decoded. The decoding of polar codes attempts to recover all information bits.

The transmitted code length M may not always be the power of 2, i.e., M<N. In practice, puncturing and shortening are used to reduce transmitted code bits from N to M. For convenience, the present disclosure hereinafter refers to N as the mother code length, and M as the code length. In particular, punctured bits are non-transmitted bits unknown to the decoder, but shortened bits are non-transmitted bits known to the decoder (usually all zeros).

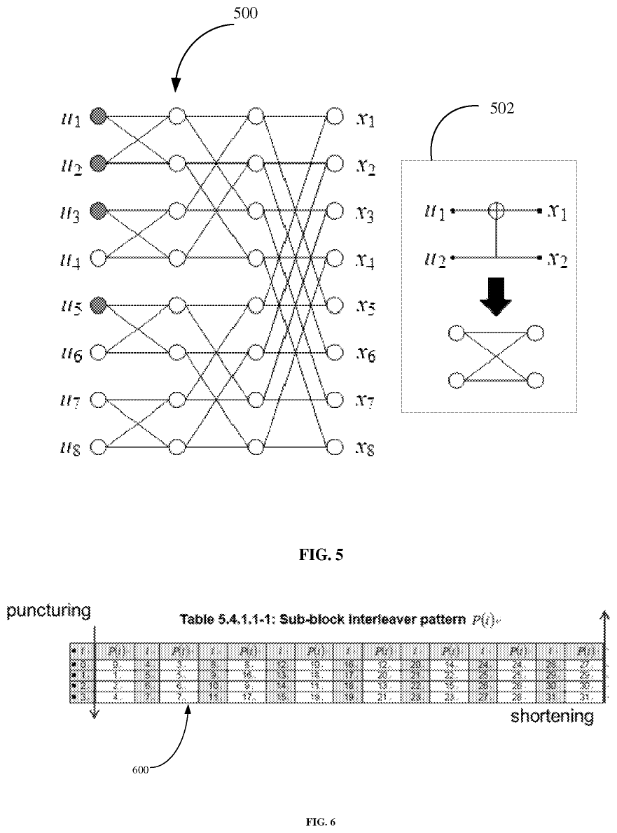

An example of a polar code with N=8, K=4 is shown in the trellis graph 500 of FIG. 5. Each “butterfly” 502 in the graph represents a polarization, i.e.,

$${x}_{1}^{2} = {u}_{1}^{2} [ \begin{matrix}1 & 0 \\ 1 & 1\end{matrix} ] .$$

In this example, the information set is I={u₄, u₆, u₇, u₈}, and the frozen set is F={u₁, u₂, u₃, u₅}.

Successive cancellation (SC) is the basic decoding algorithm for polar codes, where all the frozen bits and information bits are decoded sequentially, i.e., bit by bit. The preceding bits are typically always decoded first.

Successive cancellation list (SCL) is an enhanced decoding algorithm for polar codes, where multiple (e.g., a number L) SC decoding instances are executed. Each instance is called a “decoding path”. When decoding each binary bit, both “0” and “1” branches are extended to each path, creating 2L paths. Then, all 2L paths are compared, where the most likely L paths are kept, and the least likely L paths are discarded (or pruned). These path extension and pruning operations are performed during decoding of every information bit, until all information bits are decoded. At last, the most likely path is selected as the decoding output.

CRC-aided successive cancellation list (CA-SCL) works almost the same as SCL, except that in the last step, the most likely path that passes CRC check is selected as the decoding output.

Parity-check successive cancellation list (PC-SCL) works almost the same as SCL, except that when decoding PC bits, the parity check value of associated preceding bits is used as the bit decision result. PC bits may be considered a type of bit in addition to frozen bits and information bits.

Low Density Parity Check (LDPC) code is a channel coding scheme capable of achieving performance that approaches the Shannon limit, and furthermore features good overall performance and low complexity.

The LDPC code is encoded through a PC matrix. One class of LDPC code has a particular structure known as quasi-cyclic (QC). In a QC-LDPC code, a shifting value of each block is designed to avoid a bad structure such as a short circle, and improve a code distance. Decoding algorithms for LDPC codes include Min-Sum (MS) and Belief Propagation (BP). In terms of decoding performance, the BP decoding algorithm is better, but it has a large amount of information storage and a complex computation overhead, which is not convenient to hardware implementation. Therefore, Offset-MS and Normalized-MS decoding algorithms are used in realistic communication systems. An example LDPC code implementation extends the “1” in the basic graph (BG) by a square matrix, which is a cyclic shifted version of an identity matrix. The BG of QC-LDPC code can be defined by BG=(X, Y, F), where X corresponds to a variable, Y corresponds to a check equation, and F is its edge connections. The Tanner graph is obtained after QC lifting with an expansion factor Z_{c}. That is, a bipartite graph G=(V, C, E), where Vis a variable node, C is a check node, E is a connected edge, and a corresponding parity matrix column quantity N=|V|=Z_{c}|X|. The quantity of rows of the check matrix M=|C|=Z_{c}|Y|, and a quantity of non-zero elements of the check matrix is |E|=Z|F|.

In an example, LDPC payloads include information block lengths ranging from 1 to 8448. The LDPC code implementation includes two PC matrices: BG1 and BG2. The same base graph, lifted by different lifting sizes, can adapt to a wide set of different code rates and lengths. This flexible implementation can be achieved, for example, by storing the Lifting Size and Shifting Value lists in the look-up tables, and then performing rate matching and IR-HARQ based on the tables.

In an example rate matching scheme for LDPC codes, a codeword before rate matching (referred as a mother codeword) includes three disjoint portions or parts, i.e., systematic bits, core parity check bits and extended parity check bits. Four different redundancy versions (RVs) including RV0, RV1, RV2 and RV3 are generated from the mother codeword after rate matching. In an initial transmission, RV0 is normally selected; in RV0, most of the systematic bits are included in the set of coded bits. Depending on the effective code rate, part of the core parity bits or all of the core parity check bits and extended parity bits are included in RV0. As a result, RV0 has the highest self-decodable ability among all RVs (i.e., RV0 can be self-decodable at highest code rate). In a retransmission, the transmitter may select RV1, RV2 or RV3. In this particular example, only RV3 is self-decodable, while RV1 and RV2 are not self-decodable at high code rate. At some code rates, RV1 and RV2 may only include parity check bits, resulting in unsuccessful decoding at the receiver.

Rate-compatible polar coding is a desirable technology for wireless applications. In one example of polar code rate matching, a combination of puncturing, shortening and repetition is used together with a fixed reliability sequence to balance performance and complexity. In particular, subblock-wise interlacing and interleaving is used for both puncturing and shortening. The puncturing and shortening patterns are symmetric.

With mother code length N, and code length M, the specific rate matching scheme used is Repetition, when M>N; Puncturing, when K/M≤7/16; Shortening, when K/M>7/16;

A subblock-wise interleaving is performed before puncturing and shortening. The interleaver partitions the length-N mother code into 32 subblocks of size N/32 and interlaces them. An example interleaver scheme is shown as table 600 in FIG. 6, reproduced from a 3GPP standard specification.

Since puncturing is performed from the 1^{st} code bit, and shortening is performed from the last code bit, the rate matching module is efficiently implemented through a cyclic buffer. All mother code bits are placed in the cyclic buffer, and puncturing is done by skipping the first few bits and selecting the remaining bits for transmission in clockwise order, and shortening is done by selecting bits for transmission in clockwise order and skipping the last few bits. An example cyclic buffer is illustrated in FIG. 7.

FIG. 7 illustrates an example of a mother code 702. As shown, if puncturing is performed (e.g., when the code rate is low), the punctured bits 704 start from the first code bit. If shortening is performed (e.g., when the code rate is high), the shortened bits 706 are ending bits until the last code bit. FIG. 7 also illustrates an example of how a cyclic buffer 710 may be used for puncturing or shortening of the mother code 702. The bits of the mother code 702 are placed in the cyclic buffer 710, and the bits are selected from the cyclic buffer 710 starting at a starting position 712 and ending at an ending position 714. In an example 720 where no puncturing or shortening is performed, the starting position 712 is at the first code bit of the mother code 702 and the ending position 714 is at the last code bit of the mother code 702, such that all bits of the mother code 702 are selected. In an example 730 where puncturing is performed, the starting position 712 is shifted such that bit selection starts (N−M) bits after the first bit and the ending position 714 is at the last code bit of the mother code 702, such that (N−M) bits are punctured. In an example 740 where shortening is performed, the starting position 712 is at the first code bit of the mother code 702 and the ending position 714 is shifted such that bit selection stops (N−M) bits before the last bit, such that (N−M) bits are shortened.

Another polar code rate matching example involves an incremental freezing HARQ method, where transmissions of multiple short code words are supported. As more short codes are transmitted, the overall code length increases, and the overall code rate decreases.

In the first transmission, an (M₁, K) polar code is constructed, encoded and transmitted. The code rate is R₁=K/M₁. Usually, the code rate is determined such that R₁<C₁, where C₁ is the channel capacity of the first transmission. But in the case of faded channel or inaccurate channel estimation, there may be inequality R₁>C₁, and decoding will fail and a second transmission is required.

In the second transmission, K₂ least reliable information bits are selected from the K information bits in the first transmission. In practice, K₂ is chosen according to the estimated channel capacity of the second transmission. An (M₂, K₂) polar code is constructed accordingly and encoded and transmitted. However, if R₂>C₂, and decoding will fail again and a third transmission is required.

The third and fourth transmissions are constructed similarly, and so on.

At the receiver side, the decoder should always decode the last received code word, because it has the lowest code rate and thus the best chance of successful decoding. After the last transmission is correctly decoded, the corresponding information bits in all previous transmissions become known, and can be decoded as frozen bits with known values. This process is repeated as more code words are decoded, until all K bits in the first transmission is decoded. The term “incremental freezing” refers to the operations to additionally freeze some information bits in the previous transmissions once a later transmitted code word is decoded.

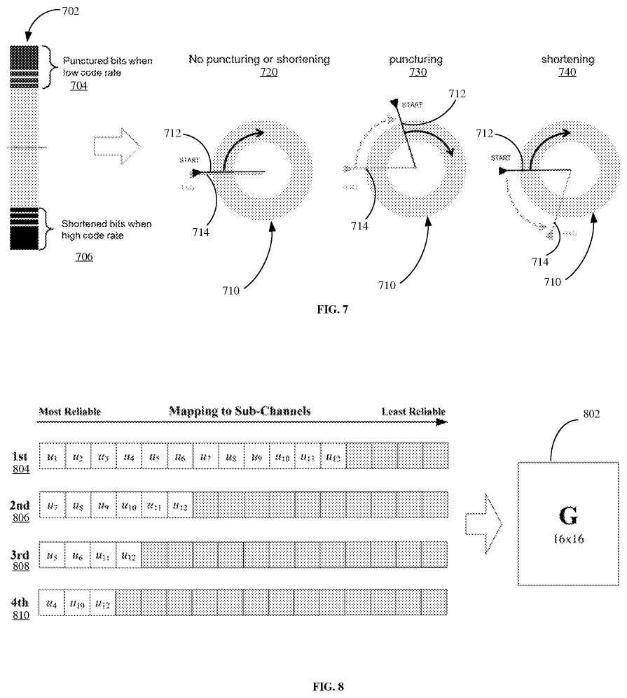

An example is illustrated in FIG. 8, where M₁=M₂=M₃=M₄=16, and K₁=12, K₂=6, K₃=4, K₄=2.

FIG. 8 illustrates an example set of sub-channels from most reliable sub-channel to least reliable sub-channel (it should be understood that the sub-channels are conceptually ordered from most reliable to least reliable, and the order illustrated in FIG. 8 may not indicate any actual ordering of the sub-channels). An example of four transmissions are shown. In this example, the code length is 16 for all four transmissions (i.e., M₁=M₂=M₃=M₄=16) meaning a 16×16 polar transformation matrix 802 (sometimes referred to as the generator matrix), indicated as G, is used for all four transmissions. The number of information bits to be transmitted is 12 (i.e., K=12).

In the first transmission 804, all 12 information bits (i.e., K₁=K=12) are selected, namely the bits {u₁, u₂, u₃, u₄, u₅, u₆, u₇, u₈, u₉, u₁₀, u₁₁, u₁₂,}. An (M₁, K₁) polar code is constructed, encoded and transmitted over the most reliable sub-channels. In the case of faded channel or inaccurate channel estimation, the code rate may exceed the channel capacity and decoding may fail. A second transmission is required.

In the second transmission 806, the K₂-th least reliable information bits are selected from the information bits sent in the first transmission 804. In this example, K₂=6 meaning that the information bits sent in the 6 least reliable sub-channels, namely the bits {u₇, u₈, u₉, u₁₀, u₁₁, u₁₂,}, are selected. An (M₂, K₂) polar code is constructed accordingly and encoded and transmitted over the most reliable sub-channels. If decoding fails again, a third transmission is required.

In the third transmission 808, the selected bits are selected from the least reliable information bits sent in the second transmission 806 as well as the least reliable bits of the first transmission 804 that have not been retransmitted. Specifically, of the K₃₌₄ information bits selected for the third transmission 808, the two least reliable information bits of the second transmission 806 are selected (namely {u₁₁, u₁₂}) and the two least reliable information bits of the first transmission 804 that have not been retransmitted are selected (namely {u₅, u₆}). An (M₃, K₃) polar code is constructed accordingly and encoded and transmitted over the most reliable sub-channels. If decoding fails again, a fourth transmission is required.

In the fourth transmission 810, the selected bits are selected from the least reliable of the not yet retransmitted information bits of all preceding transmissions. Specifically, of the K₄=3 information bits selected for the fourth transmission 810, the one least reliable information bit of the third transmission 808 is selected (namely {u₁₂}), the one least reliable of the not yet retransmitted information bits of the second transmission 806 is selected (namely {u₁₀}), and the one least reliable of the not yet retransmitted information bits of the second transmission 806 is selected (namely {u₄}). An (M₄, K₄) polar code is constructed accordingly and encoded and transmitted over the most reliable sub-channels.

In this example, decoding is successful after the fourth transmission 810. Then, using the successfully decoded information bits of the fourth transmission 810, the remaining information bits of the third transmission 808 can be decoded. The information bits of the second transmission 806 can then be decoded after successful decoding of the information bits of the third transmission 808, and so forth until all 12 information bits are successfully decoded.

PC polar codes may be used to improve minimum distance of polar codes. PC polar codes may also be used to support IR-HARQ. In the latter case, the PC bits are used to couple multiple retransmissions into a longer polar code with extra coding gain.

The PC bits may be considered an additional type of bits in addition to information and frozen bits. The values of the PC bits are determined by their preceding information bits, and specifically, by binary linear combinations of a subset of preceding information bits. The binary linear combination is specified by a PC function:

uᵢ+uⱼ+ . . . +uₖ=0,

where i<j< . . . <k are bit indices. Since k is the largest index in this PC function, uₖ may be referred to as a PC bit, whose value is the binary sum of all other (preceding) bits in the PC function.

In order to improve the minimum distance (or weight spectrum), the PC bit positions are selected from the indices among the non-frozen bit set with minimum row weights in the polar transformation matrix G_{N}. The non-frozen bit set is the complement set of the frozen set.

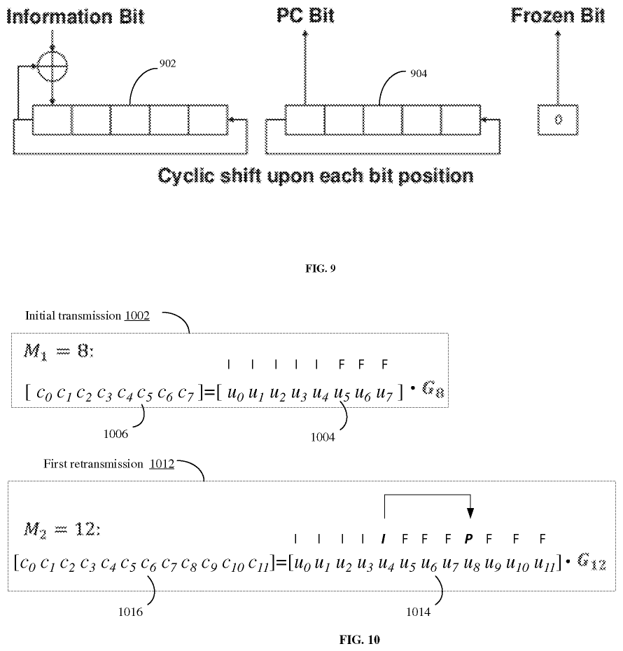

An example polar code scheme uses a simple and hardware-friendly PC function over fixed p-sized spacing. For example, p can be set to a value of 5. That is, for a PC bit with index k, its value is the sum modulo 2 of all preceding information bits with spacing 5. That is, uₖ=uₖ₋₅+uₖ₋₁₀+uₖ₋₁₅+ . . . . The PC bits can be easily generated by a p-length cyclic shift register, as shown in FIG. 9.

FIG. 9 illustrates an example of how a cyclic shift register may be used during assignment of bits to bit positions (where different bit positions correspond to different sub-channels). In this example, p has a value of 5 (i.e., a cyclic shift register that holds 5 bit values is used). For a bit position at a current index, it is determined whether that bit position should carry an information bit, a PC bit or a frozen bit. If the bit position is to carry an information bit, the bit value of the information bit is stored in a cyclic shift register 902 and the cyclic shift register 902 is shifted by one. If the bit position is to carry a PC bit, the bit value of the PC bit is outputted from the cyclic shift register 902 and the cyclic shift register 902 is shifted by one. Frozen bits in this example always have a value of 0 and after the frozen bit value is assigned to the bit position the cyclic shift register 902 is shifted by one.

Some example of PC polar codes may also be implemented to support IR-HARQ. In such examples, the PC bits may no longer primarily serve a purpose for improving minimum code distance, but rather the PC bits may primarily be for coupling multiple retransmissions into a longer polar code with extra coding gain.

The PC functions used for IR-HARQ may be considered a special case, where some information bits are copied from the initial transmitted code block to a retransmitted code block. This one-to-one parity checking between the two shorter code blocks effectively couples the two code blocks into a longer code block.

For example, the initial transmission is a (M₁=8, K=5) polar code, where {u₀, u₁, u₂, u₃, u₄} is the information set, and {u₅, u₆, u₇} is the frozen set. Its encoding process is illustrated in FIG. 10.

As shown in FIG. 10, in the encoding process for the initial transmission 1002, the bit vector 1004 contains the information bits (indicated by I) in the most reliable bit positions and the frozen bits (indicated by F) in the least reliable bit positions. The bit vector 1004 is multiplied by the polar transformation matrix G₈ to generate the code vector 1006.

In the first retransmission, four additional code bits are transmitted. These four bits are coupled with the initially transmitted 8 bits to form a (M₂=12, K=5) polar code. The coupling is achieved by copying the value of u₄ to u₈ during encoding, thus generating a PC function u₄+u₈=0 (or equivalently u₈=u₄). As said, the largest index in this PC function corresponds to the PC bit (here u₈). During decoding, u₄ is decoded as an information bit, while u₈ is decoded as a PC bit using u₈=u₄. With {u₀, u₁, u₂, u₃, u₄} as the information set, {u₈} as the PC set, and {u₅, u₆, u₇, u₉, u₁₀, u₁₁} as the frozen set, the encoding process is illustrated in FIG. 10.

As shown in FIG. 10, in the encoding process for the first retransmission 1012, the bit vector 1014 contains the information bits and frozen bits of the initial bit vector 1004, coupled to four additional bits, where one of the information bits (namely u₄) is copied to one of the added bits (namely u₈) that is used as a PC bit (indicated by P). The bit vector 1014 is multiplied by the polar transformation matrix G₁₂ to generate the code vector 1016.

In the second retransmission, the remaining four bits c₁₂, c₁₃, c₁₄, c₁₅ are transmitted to form a (M₃=16, K=5) polar code. But this time no new PC bits are generated.

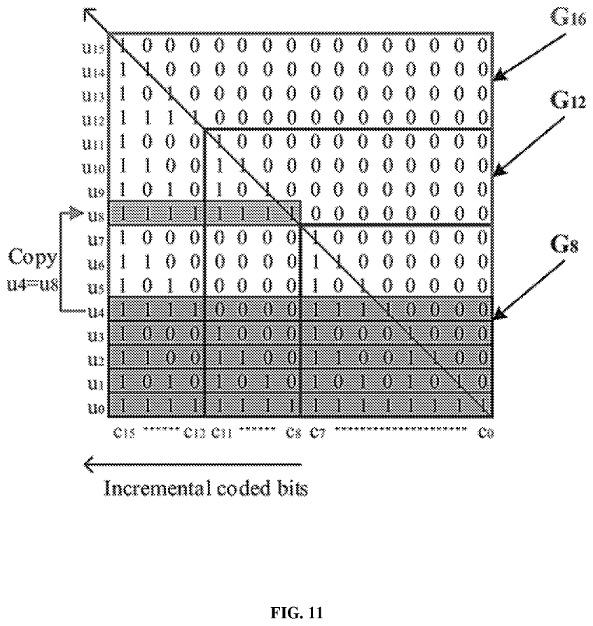

From the polar transform matrix point of view, the three transmissions with effective code lengths M₁=8, M₂=12, M₃=16, are illustrated in FIG. 11.

FIG. 11 illustrates examples of the G₈, G₁₂ and G₁₆ polar transformation matrices that may be used to perform the encoding of the initial transmission, first retransmission and second retransmission as described above. Notably, the G₁₂ and G₁₆ polar transformation matrices cause the value of u₄ to be copied to u₈ during encoding.

Rate-compatible LDPC coding is also another desirable technology for wireless applications. LDPC rate matching may involve a combination of puncturing, shortening, and repetition used together with quasi-cyclic lifting based on a base graph (BG) and a set of shifting values. In particular examples, the lifting size Z is grouped into eight sets according to Z_{c}=aⱼ×2^{k}^{ⱼ}, where aⱼ∈{2,3,5,7,9,11,13,15} and max (kⱼ)∈{7,7,6,5,5,5,4,4}. The lifting sizes derived from the same aⱼ belong to the same set, and share the same shifting value. The shifting values for all the non-zero positions in the BG and for all groups of lifting sizes are stored in a single table. During the construction of a PC matrix, the lifting size Z_{c}, is determined first, then the set index j of the lifting size is obtained, and finally the shifting value is obtained from the table.

In general, a PC polar code scheme may need to specify how to generate the PC bits using cyclic shift registers.

Some embodiments of the present disclosure include methods to generate PC bits for polar coding. The methods produce performance gain and have simple descriptions. Some embodiments of the present disclosure may include the following objectives:
To obtain a stable performance under a wide range of code lengths and rates;
To have simple description for standardization.

Methods in accordance with embodiments of the present disclosure may include one or more of the following features:
Shift register based PC encoding method;
   Feedforward and/or feedback structure;
   Clockwise or counter-clockwise shift direction;
   Input position to the registers;
   Output positions from the registers;
Bit assignment method;
   All parity bits assignment;
   Systematic bits and parity bits assignment;
   Joint PC encoding and bit assignment.

Some embodiments of the present disclosure include one or more of the following features, which can be separately adopted, or work together as a complete solution.

PC polar coding is an effective way to enhance coding performance. Similar schemes such as polarization-adjusted convolutional (PAC) codes, also apply an outer convolutional code (CC) before the polar encoding step, in order to boost performance. These PC-polar, PAC and other methods that generate assistant bits from the information block before polar encoding all belong to the same category. The general term may be called “assistant-bit-based polar coding”. However, for convenience, the various assistant-bit-based polar coding schemes may be referred to herein simply as PC-polar codes.

Usually, to facilitate hardware implementation and standard description, the PC encoding is described and implemented by a set of shift registers (e.g., the PC-polar encoding shift registers described above), with wiring and connections and output defined by a polynomial. The input is fed into the shift registers, and the values in the registers are shifted (or cyclic shifted) by one position after each information and/or frozen bit position in the length-N vector. The output can be taken from the values stored in the shift registers.

With the shift register implementation, the encoding chain may be illustrated in FIG. 12. The encoding process can be expressed as three steps.

The example encoding chain includes a PC encoding step 1202, a bit assignment step 1204 and a polar encoding step 1208. A subchannel selection module 1206 governs assignment of information bits, PC bits and frozen bits. The subchannel selection module 1206 governs what type of bit is carried by each bit position in the vector that is to be inputted to the polar encoding step 1208. Each bit position in the length-N vector (denoted

$${v}_{0}^{N - 1} )$$

that is inputted to polar encoding 1208 corresponds to a respective subchannel. The subchannel selection module 1206 performs operations that aims to assign information bits to bit positions corresponding to more reliable subchannels and to assign PC bits or frozen bits to bit positions corresponding to less reliable subchannels. For convenience, some examples will refer to “subchannel” as a shorthand for a bit position corresponding to a subchannel. The bit positions for each type of bit may be based on the information set Q_{I}, the PC set Q_{PC}, and the frozen set Q_{F}, which may be defined in accordance with a standard. Further details are provided below.

The first step is PC encoding, in which a length-K information vector

$${u}_{0}^{K - 1}$$

is PU encoded to generate J assistant bits.

$${v}_{0}^{K + J - 1} = {u}_{0}^{K - 1} {T}_{N}$$

The PC encoding can be defined by an upper-triangular pre-transformation matrix T (where N is the dimension of the matrix T, and N corresponds to the number of subchannels for the polar code), because with the shift register implementation, any parity bits must be generated preceding information bits of smaller indices.

A subchannel selection module is required to instruct both the PC encoding step and the subsequent bit assignment step. The subchannel selection module outputs the several subchannel sets, i.e., the information set Q_{I}, the PC set Q_{PC}, and the frozen set Q_{F}.

The number of assistant bits J, and where should the assistant bits be inserted into the information vector, are governed by a subchannel selection module;

The subchannel selection module determines, among the N polarized subchannels of polar codes, which K+J subchannels are for assigning PC encoded bits (may include information bits), and which N−K−J subchannels are for frozen bits.

After PC encoding, we obtain a length-(K+J) vector

$${v}_{0}^{K + J - 1} ,$$

which may contain both information bits and PC bits, or PC bits only.

When the PC codes are systematic code, the vector contains both information

$${v}_{0}^{K + J - 1}$$

contains both information bits and PC bits; for example, among the K+J bits, K bits are information bits and J bits are assistant bits.

When the PC codes are non-systematic code, the vector

$${v}_{0}^{K + J - 1}$$

contains PC bits only; as a result, the input payload bits will not appear

$${v}_{0}^{K + J - 1}$$

in at all.

In the second step, the K+J bits are assigned to polarized subchannels. When necessary, zeros are inserted in between the K+J bits to generate a length-N vector for polar encoding. In the following equation,

$${v}_{0}^{N - 1}$$

denoted the zero-padded PC encoded vector.

$${v}_{0}^{K + J - 1} \to zero filling \to {v}_{0}^{N - 1}$$

The zero-filling is also governed by the subchannel selection module, which inserts N−K−J bits with frozen bit value (typically zero, and could be masked by identifier bits).

Finally, the zero-padded vector

$${v}_{0}^{N - 1}$$

is sent for polar encoding to obtain the polar codeword

$${c}_{0}^{N - 1} .$$

$${c}_{0}^{N - 1} = {v}_{0}^{N - 1} {G}_{N}$$

The whole PC encoding can be conveniently described with a shift register implementation that may include several technical aspects, as follows.
Design of shift register based PC encoding;
   Feedforward and/or feedback structure;
   Clockwise or counter-clockwise shift direction;
   Input position to the registers;
   Output positions from the registers;
Design of bit assignment;
   All parity bits assignment;
   Systematic bits and parity bits assignment;
   Joint PC encoding and bit assignment.

Some embodiments of the present disclosure relate to a shift register based description of PC encoding implementation. These embodiments include several technical aspects, which may be described in a decoupled manner without limitation. However, it should be evident these separately described aspects may be combined in various ways into one or more complete solutions.

Some embodiments of the present disclosure relate to employing shift registers for PC encoding as a pre-coding for polar codes.

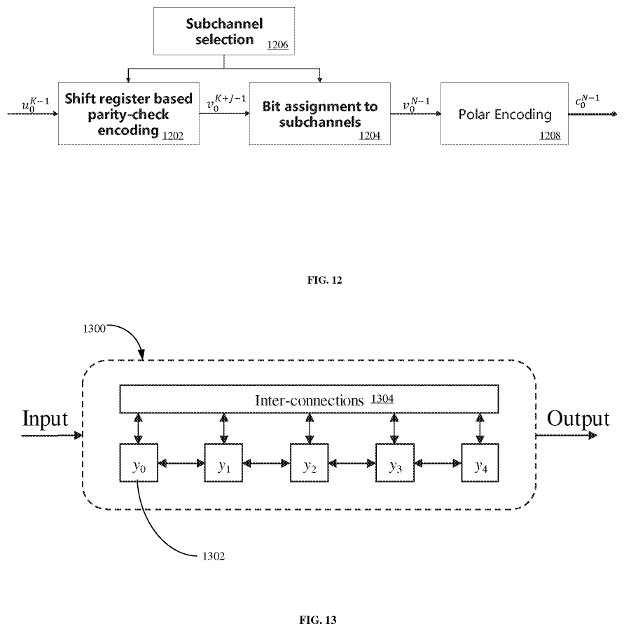

The basic structures of shift registers for generating PC bits for polar encoding are shown in FIG. 13. For ease of understanding, examples are described herein with reference to a shift register, however it should be understood that such examples may be implemented using hardware and/or software within the scope of the present disclosure. Additionally, FIG. 13 illustrates only an example of how a shift operation may be implemented using a shift register. It should be understood that the shift operation represented by the shift register of FIG. 13 may be implemented in other ways, for example using logic instead.

FIG. 13 illustrates an example of a shift register 1300 having five elements 1302, each of which stores a single bit value. Each element 1302 may be implemented using a flip-flop or other suitable circuit component. In some instances, each element 1302 may be referred to as a single register (i.e., a 1-bit register) and the shift register 1300 may be referred to as a set of registers, an array of shift registers or a set of shift registers. A shift register having elements 1302 that are connected in a cyclical manner (i.e., the last indexed element has a connection to the first indexed element) may be referred to as a cyclic shift register or a set of cyclic shift registers. There may be one or more interconnections 1304 between elements 1302. As disclosed herein, interconnections 1304 between elements 1302 may be implemented using hardware (e.g., wired connections) or software (e.g., logical combination of bit values using XOR operations). It should be understood that the various shift registers described with reference to FIGS. 13-18 are representations of shift operations that may be equivalently implemented using software only or a combination of software and hardware. The shift operations may operate on an array of elements, which may or may not be physically connected memory elements (e.g., the elements in the array of elements may be at different memory locations but logically connected such that the bit values stored in the elements can be shifted from one element to the next) The pseudocode and logic for implementing the shift operations illustrated by FIGS. 13-18 are encompassed by the present disclosure. Thus, the present disclosure is not limited to hardware implementations of the cyclic shift operation.

Each shift register stores one bit, which can be read out or written in by an external controller.

A number of registers are placed in an array, and they form a chain.

Adjacent registers are physically or logically connected, and the bit stored in one shift register can be read out and written into an adjacent register. This operation is known as “shifting”.

Non-adjacent registers can also be inter-connected through “wire connections”, which may be physical connections or logical connections depending on the particular hardware implementation.

The whole shift register module has an input and an output.

The output bits are assigned to polarized subchannels for polar encoding.

The direction of register shifting may be clockwise or counter-clockwise.

Clockwise shift, which may also be called low-to-high shift, or left-to-right shift.

In pseudocodes, if the shift register bit updating follows a low-to-high order, then the following bit assigning operations are performed: [symbol] ₁= [symbol] ₗ₋₁, [symbol] ₗ₋₁= [symbol] ₗ₋₂, . . . , [symbol] ₂= [symbol] ₁, [symbol] ₁= [symbol] ₀.

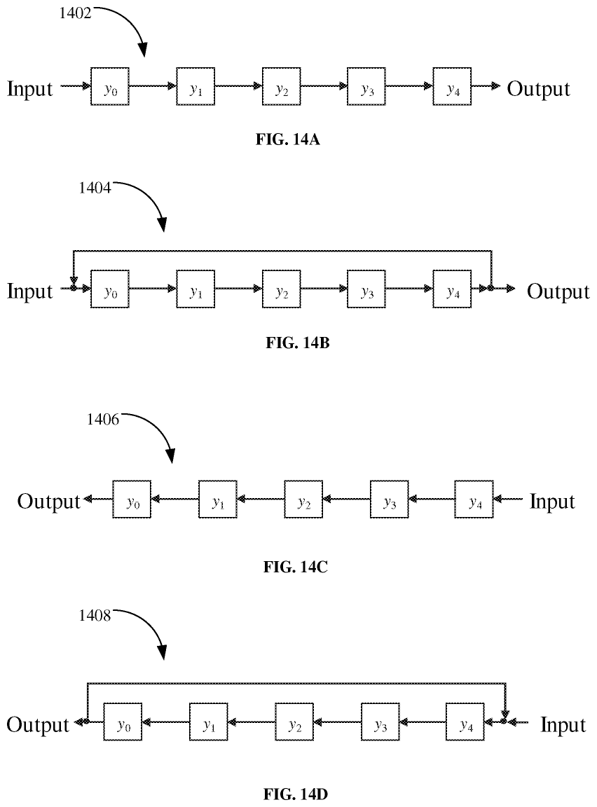

An example of the clockwise shift is illustrated in FIG. 14A. In this example, the shift operation is implemented using a shift register, but this is not intended to be limiting. The shift operation illustrated in FIG. 14A may be implemented by any hardware and/or software implementation in which a shift by one means that the bit values are assigned as follows: [symbol] ₄= [symbol] ₃, [symbol] ₃= [symbol] ₂, [symbol] ₂= [symbol] ₁, [symbol] ₁= [symbol] ₀.

As shown in FIG. 14A, a clockwise shift register 1402 is connected such that the direction of shift is from the lowest indexed element ( [symbol] ₀) to the highest indexed element ( [symbol] ₄). This may be referred to as a clockwise shift direction, a shift direction from lowest index to highest index, or a shift direction from least significant bit (LSB) to most significant bit (MSB) (e.g., where the lowest index element corresponds to the LSB and the highest index element corresponds to the MSB). The terms “upstream” and “downstream” may be used to refer to one element relative to another element, with reference to the shift direction. For example, element [symbol] ₄ is a downstream element relative to element [symbol] ₂, because the direction from [symbol] ₂ to [symbol] ₄ is in the same direction as the shift direction; on the other hand, element [symbol] ₀ is an upstream element relative to element [symbol] ₂, because the direction from [symbol] ₂ to [symbol] ₀ is opposite to the shift direction.

If a cyclic shift is supported and shift register bit updating follows a low-to-high order, the following bit assigning operations are performed: [symbol] ₜₘₚ= [symbol] ₗ, [symbol] ₗ= [symbol] ₗ₋₁, [symbol] ₗ₋₁= [symbol] ₗ₋₂, . . . , [symbol] ₂= [symbol] ₁, [symbol] ₁= [symbol] ₀, [symbol] ₀= [symbol] ₜₘₚ.

An example of the clockwise cyclic shift is illustrated in FIG. 14B. In this example, the cyclic shift operation is implemented using a cyclic shift register, but this is not intended to be limiting. The cyclic shift operation illustrated in FIG. 14B may be implemented by any hardware and/or software implementation in which a shift by one means that the bit values are assigned as follows: [symbol] ₜₑₘₚ= [symbol] ₄, [symbol] ₄= [symbol] ₃, [symbol] ₃= [symbol] ₂, [symbol] ₂= [symbol] ₁, [symbol] ₁= [symbol] ₀, [symbol] ₀= [symbol] ₜₑₘₚ.

The clockwise cyclic shift register 1404 is similar to the clockwise shift register 1402 of FIG. 14A, but with the addition of a connection from the highest indexed element ( [symbol] ₄) to the lowest indexed element ( [symbol] ₀).

Counter-clockwise shift, which may also be called high-to-low shift, or right-to-left shift.

In pseudocodes, if the shift register bit updating follows a high-to-low order, then the following bit assigning operations are performed: [symbol] ₀= [symbol] ₁, [symbol] ₁= [symbol] ₂, . . . , [symbol] ₗ₋₁= [symbol] ₁.

FIG. 14C illustrates an example of a counter-clockwise shift register 1406. The counter-clockwise shift register 1406 is connected such that the direction of shift is from the highest indexed element ( [symbol] ₄) to the lowest indexed element ( [symbol] ₀). This may be referred to as a counter-clockwise shift direction, a shift direction from highest index to lowest index, or a shift direction from MSB to LSB. In this example, the shift operation is implemented using a shift register, but this is not intended to be limiting. The shift operation illustrated in FIG. 14C may be implemented by any hardware and/or software implementation in which a shift by one means that the bit values are assigned as follows: [symbol] ₀= [symbol] ₁, [symbol] ₁= [symbol] ₂, [symbol] ₂= [symbol] ₃, [symbol] ₃= [symbol] ₄.

If a cyclic shift is supported and shift register bit updating follows a low-to-high order, the following bit assigning operations are performed: [symbol] ₜₘₚ= [symbol] ₀, [symbol] ₀= [symbol] ₁, [symbol] ₁= [symbol] ₂, . . . , [symbol] ₗ₋₁= [symbol] ₗ, [symbol] ₗ= [symbol] ₜₘₚ.

This may be referred to as a counter-clockwise cyclic shift register. FIG. 14D illustrates an example of a counter-clockwise cyclic shift register 1408. As shown in FIG. 14D, the counter-clockwise cyclic shift register 1408 has a connection from the lowest indexed element ( [symbol] ₀) to the highest indexed element ( [symbol] ₄). In this example, the cyclic shift operation is implemented using a cyclic shift register, but this is not intended to be limiting. The cyclic shift operation illustrated in FIG. 14D may be implemented by any hardware and/or software implementation in which a shift by one means that the bit values are assigned as follows: [symbol] ₜₑₘₚ= [symbol] ₀, [symbol] ₀= [symbol] ₁, [symbol] ₁= [symbol] ₂, [symbol] ₂= [symbol] ₃, [symbol] ₄= [symbol] ₅, [symbol] ₅= [symbol] ₜₑₘₚ.

The structure of a shift register may include feedforward, feedback, or both feedforward and feedback.

Feedforward: the interconnections between two registers are directional, and the direction is the same as the direction of register shifting, or toward the output direction;

In pseudocodes, if the shift register bit updating follows a low-to-high order, i.e. [symbol] ₗ= [symbol] ₗ₋₁, [symbol] ₗ₋₁= [symbol] ₗ₋₂, . . . , [symbol] ₂= [symbol] ₁, [symbol] ₁= [symbol] ₀, then a feedforward interconnection may be described as

yₖ=yᵢ⊕yⱼ, where i<k and j<k. The ⊕, that is, XOR may be performed on more than two shift values.

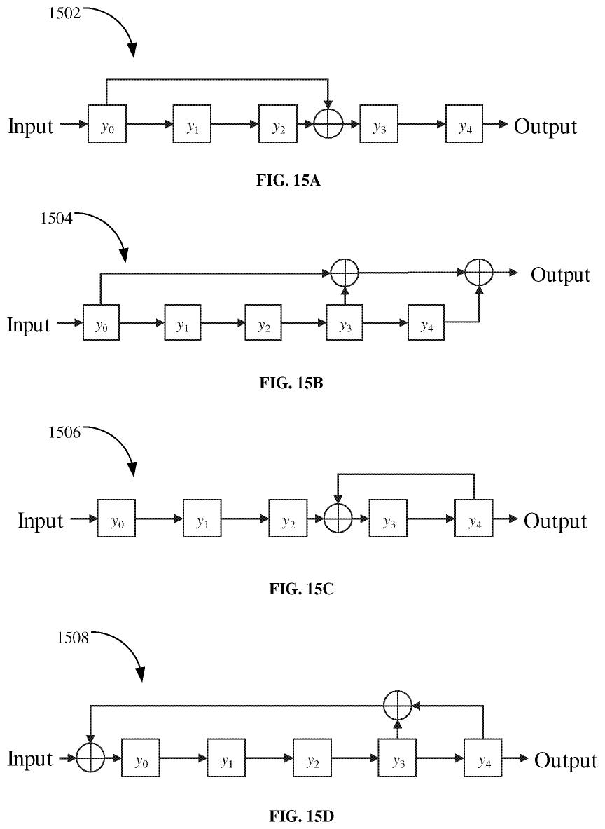

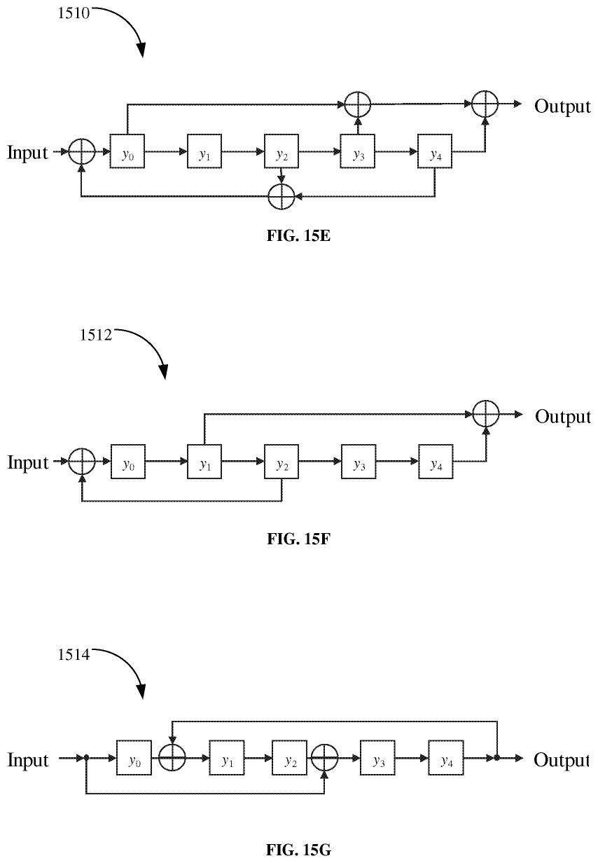

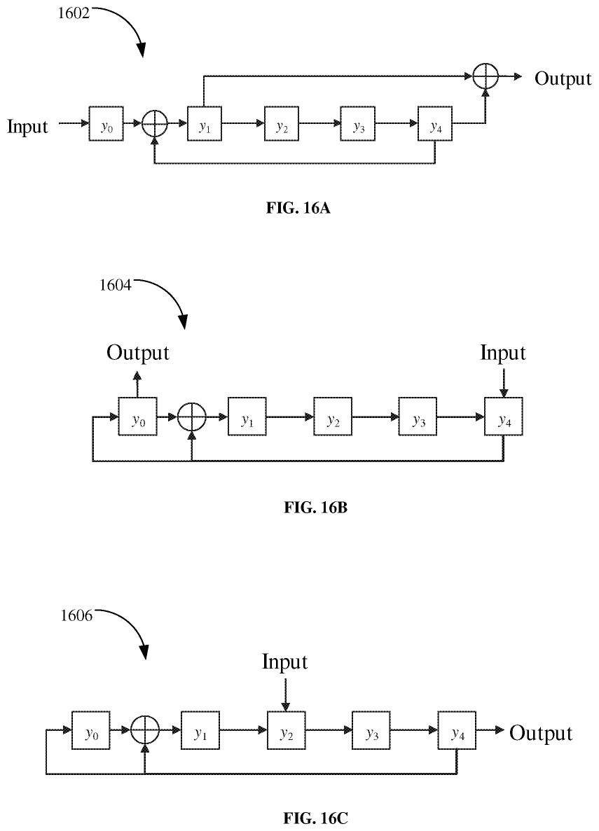

An example of feedforward inter-connection (y₃=y₀ ⊕y₂) is illustrated in FIG. 15A.

FIG. 15A illustrates an example shift register 1502 having a shift direction from lowest index to highest index. The shift register 1502 includes an interconnection that results in the bit value of at least one element being based on a combination of two or more other elements, in this case y₃=y₀ ⊕y₂. The shift direction is from lowest index to highest index, thus elements upstream of y₃ are elements having lower index and elements downstream of y₃ are elements having higher index. The interconnection is in a feedforward direction because the value of the element y₃ is a combination of elements that are upstream of y₃. Put another way, the interconnection is in the same direction as the shift direction such that bit values of upstream elements are combined at a downstream element.

Another type of feedforward inter-connection is directly connected to output. The pseudocodes may be yₒᵤₜ=yᵢ⊕yⱼ, where yₒᵤₜ is the output value. The XOR may be performed on more than two shift values.

An example of feedforward inter-connection (yₒᵤₜ=y₀ ⊕y₃ ⊕y₄) is illustrated in FIG. 15B.

In FIG. 15B, the example shift register 1504 has a shift direction from lowest index to highest index. Additionally, the shift register 1504 has interconnections that result in the bit value at the output being based on a combination of multiple elements, in this case yₒᵤₜ=y₀⊕y₃⊕y₄. In this example, the output is based on a combination of elements that are upstream of yₒᵤₜ. The interconnections are in a feedforward direction, because the interconnections to the output are all in the same low-to-high direction as the shift direction.

Feedback: the interconnections between two registers are directional, and the direction is the opposite to the direction of register shifting;

In pseudocodes, if the shift register bit updating follows a low-to-high order, i.e. [symbol] ₗ= [symbol] ₗ₋₁, [symbol] ₗ₋₁= [symbol] ₗ₋₂, . . . , [symbol] ₂= [symbol] ₁, [symbol] ₁= [symbol] ₀, then a feedback interconnection may be described as yₖ=yᵢ⊕yⱼ, where i>k or j>k. The XOR may be performed on more than two shift values.

An example of feedback inter-connection (y₃=y₂⊕y₄) is illustrated in FIG. 15C.

FIG. 15C illustrates an example shift register 1506 having a shift direction from lowest index to highest index. The shift register 1506 includes an interconnection that results in at least bit value at one element being based on a combination of two or more other elements, in this case y₃=y₂ ⊕y₄. The shift direction is from lowest index to highest index, thus elements upstream of y₃ are elements having lower index and elements downstream of y₃ are elements having higher index. The interconnection is in a feedback direction because the value of the element y₃ is a combination of elements including at least one element downstream of y₃ (specifically, y₄ is downstream of y₃). Put another way, the interconnection is in a direction that is opposite to the shift direction such that the bit value of at least one downstream element is combined at an upstream element.

Another type of feedback inter-connection is directly connected to input. The pseudocodes may be yᵢ=yᵢₙ ⊕yⱼ, where yᵢₙ is the input value. The XOR may be performed on more than two shift values.

An example of feedforward inter-connection (y₀=yᵢₙ ⊕y₃ ⊕y₄) is illustrated in FIG. 15D.

In FIG. 15D, the example shift register 1508 has a shift direction from lowest index to highest index. Additionally, the shift register 1508 has interconnections that result in the bit value at the input being based on a combination of multiple elements, such that the value written into the lowest index element in this case becomes y₀=yᵢₙ⊕y₃⊕y₄. In this example, the input combines with elements that are downstream of yᵢₙ. The interconnections are in a feedback direction because the interconnections to the input are in a direction opposite to the low-to-high direction of the shift direction.

Both feedforward and feedback: the interconnections between two registers are directional, and the directions include those that are same as the direction of register shifting, and also those that are opposite to the direction of register shifting;

The above-mentioned feedforward and feedback methods can be combined in the same array of shift registers.

In pseudocodes, if the shift register bit updating follows a low-to-high order, i.e. [symbol] ₗ= [symbol] ₗ₋₁, [symbol] ₗ₋₁= [symbol] ₗ₋₂, . . . , [symbol] ₂= [symbol] ₁, [symbol] ₁= [symbol] ₀, then the proposed array of shift registers involve both a feedforward interconnection described as yₖ=yᵢ⊕yⱼ, where i<k and j<k, and a feedback interconnection described as yₗ=yₘ⊕yₙ, where m>l or n>l. The XOR may be performed on more than two shift values.

An example of feedforward inter-connection (y₀=yᵢₙ⊕y₂⊕y₄, and yₒᵤₜ=y₀⊕y₃ Øy₄) is illustrated in FIG. 15E.

In FIG. 15E, the example shift register 1510 has a shift direction from lowest index to highest index. The shift register 1510 has feedforward interconnections that result in the bit value at the output being based on a combination of multiple upstream elements, in this case yₒᵤₜ=y₀⊕y₃⊕y₄. Additionally, the shift register 1510 has feedback interconnections from multiple elements to the input, such that the bit value written into the lowest index element in this case is based on a combination of elements including at least one downstream element, in this case y₀=yᵢₙ⊕y₃⊕y₄. Thus, the shift register 1510 has both feedforward and feedback interconnections.

The direction of wire connections in the shift register may include out from the registers or into the registers.

The interconnections are directional, and each wire has its input and output. In one case, the input may directly come from a register. The register is not the outputting register (neither the leftmost register, nor the rightmost register). The output of the wire may directly go to the output, or the input register.

The “outgoing” feature is compatible with both feedforward and feedback methods.

In pseudocodes, if the shift register bit updating follows a low-to-high order, i.e. [symbol] ₗ= [symbol] ₗ₋₁, [symbol] ₗ₋₁= [symbol] ₗ₋₂, . . . , [symbol] ₂= [symbol] ₁, [symbol] ₁= [symbol] ₀, then one outgoing connection may be yₒᵤₜ=yᵢ⊕yⱼ, where yₒᵤₜ is the output value and both yᵢ and yⱼ are outgoing registers if they are not the output register. Another outgoing connection may be yᵢ=yᵢₙ ⊕yⱼ, where yᵢₙ is the input value and yⱼ is an outgoing register if it is not the output register.

An example of outgoing inter-connection (y₀=yᵢₙ⊕y₂, and yₒᵤₜ=y₁Øy₄, where y₁ and y₂ are outgoing registers) is illustrated in FIG. 15F.

In FIG. 15F, the input of the shift register 1512 is at the lowest index element y₀ and the output is at the highest index element y₄. There is a feedback interconnection from the outgoing element y₂ (also referred to as the outgoing register) to the input, such that the bit value at y₀ is based on a combination of yᵢₙ and downstream element y₂, in this case y₀=yᵢₙ⊕y₂. There is a feedforward interconnection from another outgoing element y₁ (also referred to as the outgoing register) to the output, such the bit value at the output is based on a combination of upstream elements y₁ and y₄, in this case yₒᵤₜ=y₁⊕y₄. Thus, an outgoing interconnection may be understood to refer to a feedforward or feedback interconnection that results in the input or output bit value to be based on a combination of other elements.

The interconnections are directional, and each wire has its input and output. In another case, the output may directly go to a register. The register is not the outputting register (neither the leftmost register, nor the rightmost register).

The “incoming” feature is compatible with both feedforward and feedback methods.

In pseudocodes, if the shift register bit updating follows a low-to-high order, i.e. [symbol] ₗ= [symbol] yₗ₋₁, [symbol] ₗ₋₁= [symbol] ₗ₋₂, . . . , [symbol] ₂= [symbol] ₁, [symbol] ₁= [symbol] ₀, then one incoming connection may be yₗ=yⱼ, where i<j and yⱼ is the incoming value and y; is an incoming register if it is not the input register. Another incoming connection may be yₖ=yᵢₙ, where yᵢₙ is the input value and yₖ is an incoming register if it is not the output register.

An example of incoming inter-connection (y₁=y₀⊕y₄, and y₃=yᵢₙ⊕y₂, where y₁ and y₃ are incoming registers) is illustrated in FIG. 15G.

In FIG. 15G, the input of the shift register 1514 is at the lowest index element y₀ and the output is at the highest index element y₄. There is a feedback interconnection from the output to the incoming element y₂ (also referred to as an incoming register), such that y₁=y₀⊕y₄. There is a feedforward interconnection from the input to another incoming element y₃ (also referred to as an incoming register), such that y₃=yᵢₙ⊕y₂. Thus, an incoming interconnection may be understood to refer to a feedforward or feedback interconnection that causes the bit value at the input or output to be based on a combination of elements.

Some embodiments of the present disclosure relate to shift register configurations including bit input position and bit output positions.

Bit input at either of the two ends of the shift register chain. The input is directly fed to y₀ the leftmost (or lowest-indexed) register, or yₗ the rightmost (or highest-indexed) register.

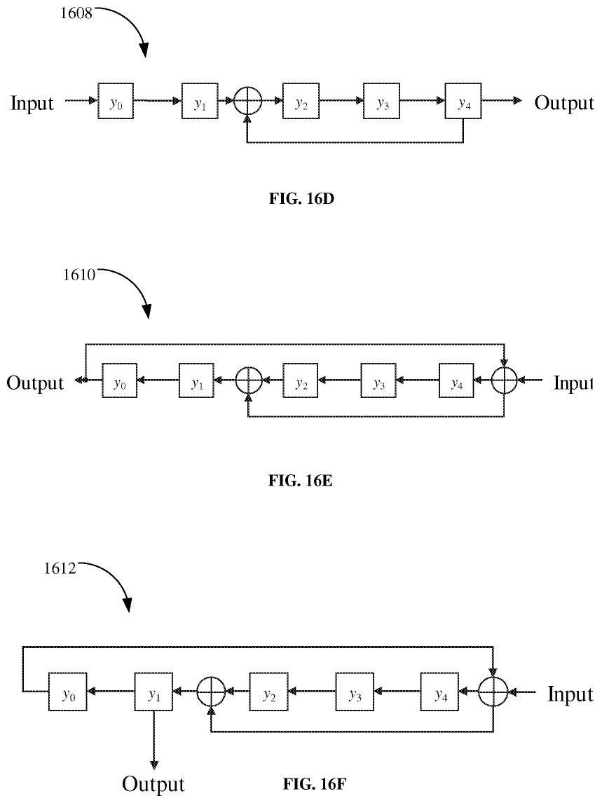

An example is given in FIG. 16A, where y₀=yᵢₙ and the input bit is fed to the leftmost register.

The example shift register 1602 is an example where the input of the shift register 1602 is at the lowest index element y₀. The shift register 1602 has a lowest-to-highest index shift direction, and also includes feedforward and feedback interconnections. The shift register 1602 may represent an example shift operation where the input is at the lowest index element. The shift register 1602 also represents an example shift operation where the input is at the most upstream element (in this case, the most upstream element is the lowest index element because the shift direction is lowest-to-highest index).

Another example is given in FIG. 16B, where y₄=y₁=yᵢₙ and the input bit is fed to the rightmost register.

The example shift register 1604 is an example where the input of the shift register 1604 is at the highest index element y₄. The shift register 1604 has a lowest-to-highest index shift direction, and also includes feedback interconnections. The shift register 1604 may represent an example shift operation where the input is at the highest index element. The shift register 1604 also represents an example shift operation where the input is at the most downstream element (in this case, the most downstream element is the highest index element because the shift direction is lowest-to-highest index).

The examples of FIGS. 16A and 16B have the input of the shift register at one end and the output at the opposite end (i.e., if input is at the lowest index element then output is at the highest index element, and vice versa). However, this is not intended to be limiting, as discussed below.

Bit input in the middle of the shift register chain: the input is fed to y; which is neither the leftmost (or lowest-indexed) register, nor the rightmost (or highest-indexed) register. Thus, 0<i<l, where l is the index of the rightmost register.

An example is given in FIG. 16C, where yᵢₙ=yₗ=y₂ and the input bit is fed to the i-th register (i=2).

In the example shift register 1606, the input is at a middle element y₂ (it should be noted that the term “middle” element is not intended to refer to strictly the centermost element of the shift register, but rather refers to an element that is not the lowest index or highest index element; in some examples, the term inner element may be used to refer to an element other than the lowest or highest index element) and the output is at the highest index element y₄. The shift register 1606 has a lowest-to-highest index shift direction, and also includes feedback interconnections. The shift register 1606 may represent an example shift operation where the input is at an inner element. The shift register 1606 also represents an example shift operation where the input is an element other than the most upstream and the most downstream elements.

Bit output at two ends of the shift register chain: The output is directly taken from y₀ the leftmost (or lowest-indexed) register, or yₗ the rightmost (or highest-indexed) register.

An example is given in FIG. 16D, where yₒᵤₜ=yₗ=y₄ and the output bit is taken from the rightmost register.

In the example shift register 1608, which has a shift direction from lowest-to-highest index, the output is at the highest index element y₄, while the input is at the lowest index element y₀. The shift register 1608 also includes a feedback interconnection. The shift register 1608 may represent an example shift operation where the output is at the highest index element. The shift register 1608 also represents an example shift operation where the output is at the most downstream element (in this case, the most downstream element is the highest index element because the shift direction is lowest-to-highest index).

Another example is given in FIG. 16E, where yₒᵤₜ=y₀ and the output bit is taken from the leftmost register.

In the example shift register 1610, which has a shift direction from highest-to-lowest index, the input is at the highest index element y₄, while the output is at the lowest index element y₀. The shift register 1610 is a cyclic shift register and also has a feedforward interconnection. The shift register 1610 may represent an example shift operation where the output is at the lowest index element. The shift register 1610 also represents an example shift operation where the output is at the most downstream element (in this case, the most downstream element is the lowest index element because the shift direction is highest-to-lowest index).

It should be understood that in yet other examples, the output of the shift operation may be at the most upstream element (e.g., the lowest index element if the shift direction is lowest-to-highest index).

Bit output in the middle of the shift register chain: the output is taken from y; which is neither the leftmost (or lowest-indexed) register, nor the rightmost (or highest-indexed) register. Thus, 0<i<l, where l is the index of the rightmost register.

An example is given in FIG. 16F, where yₒᵤₜ=yᵢ=y₁ and the input bit is fed to the i-th register (i=1).

In the example shift register 1612, which has a shift direction from highest-to-lowest index, the input is at the highest index element y₄, and the output is at an inner element y₁. The shift register 1612 is a cyclic shift register and has a feedforward interconnection. The shift register 1612 may represent an example shift operation where the output is from an inner element. The shift register 1612 also represents an example shift operation where the output is from an element other than the most upstream and the most downstream elements.

Some embodiments of the present disclosure relate to shift register configurations including whether to output information bits.

Do not output information bits: as one option, all output bits are from a shift register, or the XOR value from multiple registers (may include an input value). In this case, no information bits will be directly outputted to

$${v}_{0}^{K + J - 1} ,$$

in which none or tne K+J bits are information bits. According to this notation, there are K+J information bits.

In one example, the output bit is always from a register (y₄ in this case).

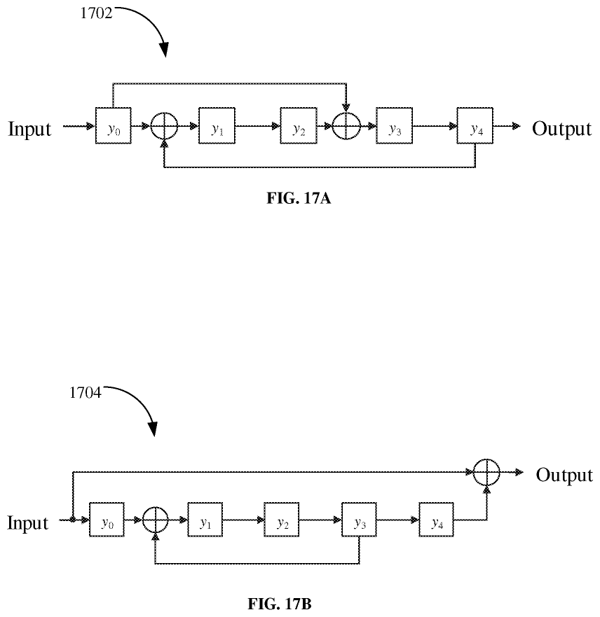

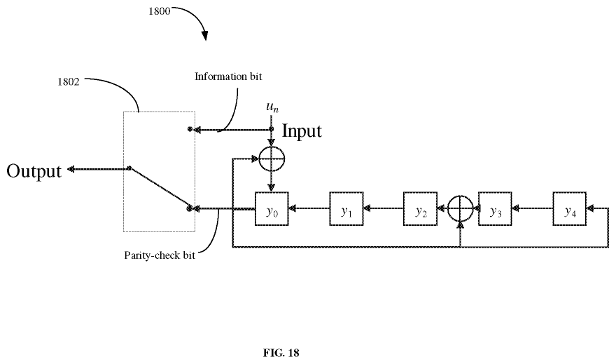

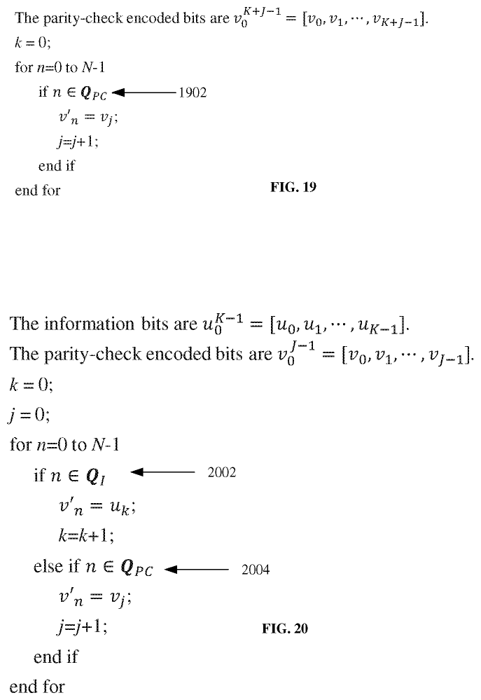

An example is shown in FIG. 17A.

In the example shift register 1702, the input (where the bit value of an information bit written to the shift register 1702) is at the lowest index element y₀. The output (where the bit value of a PC bit is read from the shift register 1702) is at the highest index element y₄. The shift register 1702 also includes feedback and feedforward interconnections. Thus, the output from the shift register 1702 will not be a direct output of the input bit value. All the bits in the PC encoded vector are outputs from an element of the shift register 1702 and not a direct copy of a prior information bit previously written to the input of the shift register 1702.

In another example, the output bit is the XOR value of a register (y₄ in this case) and the input value.

An example is shown in FIG. 17B.

In the example shift register 1704, the input (where the bit value of an information bit written to the shift register 1704) is at the lowest index element y₀. The output (where the bit value of a PC bit is read from the shift register 1704) is the XOR of y₄ with yᵢₙ. Thus, the output from the shift register 1704 will not be a direct output of the input bit value. All the bits in the PC encoded vector are outputs from an element of the shift register 1704 and not a direct copy of a prior information bit previously written to the input of the shift register 1704.

For bit indices belonging to the frozen set, i.e., i∈Q_{F}, a pre-defined value (e.g., 0 or masking bit such as an identifier) which is known to the receiver is assigned to the subchannel.

In another example case, all subchannels belong to a PC set, and there are no frozen bits. That is |Q_{PC}|=J=N, where Nis the mother code length, and J is the number of assistant bits (e.g., PC bits).

In another example case, all subchannels belong to either PC set or pre-freezing (or pre-frozen) set. The pre-freezing bits are those pre-frozen due to rate matching, and may not be frozen due to low reliability. Denote by Q_{PF} the pre-freezing set, and |Q_{PC}|+|Q_{PF}|=J+S=N, where Nis the mother code length, S is the number of pre-frozen bits, and J is the number of assistant bits (e.g., PC bits).

The above two methods may be considered to convert all the frozen bits (except those pre-freezing bits) to PC bits. This will improve the code weight spectrum and thus yield additional coding gain.

At an information subchannel (bit position), the register does not output any bit value; instead the information bit value (the input of the shift registers) is directly outputted. The information bit value is directly assigned to the information subchannel.

Therefore, the output of the PC encoder depends on the current bit index. If the current bit index belongs to the information set, i.e., i∈Q_{I}, the next input information bit is selected as the output; if the current bit index belongs to the PC set, i.e., i∈Q_{PC}, the output of the shift registers is selected as the output.

For bit indices belonging to the frozen set, i.e., i∈Q_{F}, a pre-defined value (e.g., 0 or masking bit such as an identifier) which is known to the receiver is assigned to the subchannel.

An example is shown in FIG. 18.

The example shift register 1800 may be used to implement a cyclic shift operation on an array of five elements, and may be used to generate a PC encoded vector. The shift register 1800 has a MSB to LSB (i.e., highest index element to lowest index element) shift direction and is a cyclic shift register (i.e., there is a connection between the highest and lowest index elements). The input of the shift register 1800 is at the lowest index element y₀. The output of the shift register 1800 is at the element y₀. The bit value that is to be used for output to the PC encoded vector may be selectable (e.g., using a switch 1802, which may be governed by the subchannel selection module 1206 discussed previously with respect to FIG. 12) between output of an information bit or output of a PC bit from the shift register 1800. To generate a PC encoded vector

$${v}_{0}^{K + J - 1} ,$$

the current bit index i is advanced one at a time. If the current bit index belongs to the information set, i.e., i∈Q_{I} (which may be determined by the subchannel selection module 1206), the n-th element uₙ of the information vector

$${u}_{0}^{K - 1}$$

is outputted to vᵢ, the bit value of uₙ is written to the shift register 1800 at the input, the shift register 1800 is shifted by one, and n is advanced by one. If the current bit index belongs to the PC set, i.e., i∈Q_{PC} (which may be determined by the subchannel selection module 1206), the bit value is read from the output of the shift register 1800 to vᵢ and the shift register 1800 is shifted by one. If the current bit index belongs to the frozen set i.e., i∈Q_{F} (which may be determined by the subchannel selection module 1206), then vᵢ is set to the fixed frozen bit value (e.g., bit value of 0) and the shift register 1800 is shifted by one.

It should be understood that the cyclic shift operation described above with respect to the shift register 1800 may be implemented in a manner other than using the shift register 1800. For example, a logic implementation may be used instead, where the array of elements correspond to memory locations and the elements are logically connected (rather than being connected by a wire connection, for example).

In an example case, all subchannels belong to either information set or PC set, and there are no frozen bits. That is |Q_{I}|+|Q_{PC}|=K+J=N, where N is the mother code length, K is the number of information bits (may include CRC bits), and J is the number of assistant bits (e.g., PC bits).

In another example case, all subchannels belong to either information set or PC set or pre-freezing (or pre-frozen) set. The pre-freezing bits are those pre-frozen due to rate matching, and may not be frozen due to low reliability. Denote by Q_{PF} the pre-freezing set, and |Q_{I}|+|Q_{PC}|+|Q_{PF}|=K+J+S=N, where N is the mother code length, S is the number of pre-frozen bits, K is the number of information bits (may include CRC bits), and J is the number of assistant bits (e.g., PC bits).

The above two methods may be considered to convert all the frozen bits (except those pre-freezing bits) to PC bits. This will improve the code weight spectrum and thus yield additional coding gain.

Some embodiments of the present disclosure relate to shift register configurations including bit assignment.

A bit assignment procedure maps the output bits from the PC encoder to polarized subchannels. The bit assignment function, together with the shift register-based parity check encoding, is performed according to the subchannel selection module, which specifies the information set Q_{I}, the PC set Q_{PC}, and the frozen set Q_{F}, or the pre-freezing set Q_{PF}.

In an example, where there are only PC bits, the encoding may be expressed in the pseudocode shown in FIG. 19.

In the example pseudocode of FIG. 19, the PC bits stored in the vector

$${v}_{0}^{K + J - 1}$$

are assigned to bit positions of the vector v′ (where each bit position corresponds to a subchannel). In the case where all elements of the PC encoded vector

$${v}_{0}^{K + J - 1}$$

are PC bits, then v′ₙ contains a PC bit for all n and the condition at line 1902 is always true because all bit positions belong to the PC set Q_{PC}. The pseudocode generates the vector v′ in which all PC bits have been assigned to the appropriate bit positions. Then polar encoding may be performed using a polar encoder matrix G_{N}.

The output after encoding d=[d₀ d₁ d₂ . . . d_{N-1}] is obtained by d=v′G_{N}. The encoding is performed in GF(2).

In another example, where there are only information bits and PC bits, the encoding may be expressed in the pseudocode shown in FIG. 20.

In the example pseudocode of FIG. 20, the information bits stored in the vector

$${u}_{0}^{K - 1}$$

and the PC bits stored in the vector

$${v}_{0}^{J - 1}$$

are assigned to bit positions of the vector v′ (where each bit position corresponds to a subchannel). At line 2002, it is determined whether a given n-th bit position belongs to the information set Q_{I}; if so, then the current information bit is assigned to bit position v′ₙ and the index of information bits is advanced by one. At line 2004, it is determined whether a given n-th bit position belongs to the PC set Q_{PC}; if so, then the current PC bit is assigned to bit position v′ₙ and the index of PC bits is advanced by one. The pseudocode generates the vector v′ in which all information bits and PC bits have been mapped to the appropriate bit position. In examples where the PC bits are generated from preceding information bits, bit positions at an index smaller than the smallest information bit index may be assigned a PC bit that has a fixed value (e.g., a frozen bit value) or a preset value (e.g., from a set of predefined bit values). Polar encoding may be performed on the vector v′ using a polar encoder matrix G_{N}.

The output after encoding d=[d₀ d₁ d₂ . . . d_{N-1}] is obtained by d=v′G_{N}. The encoding is performed in GF(2).

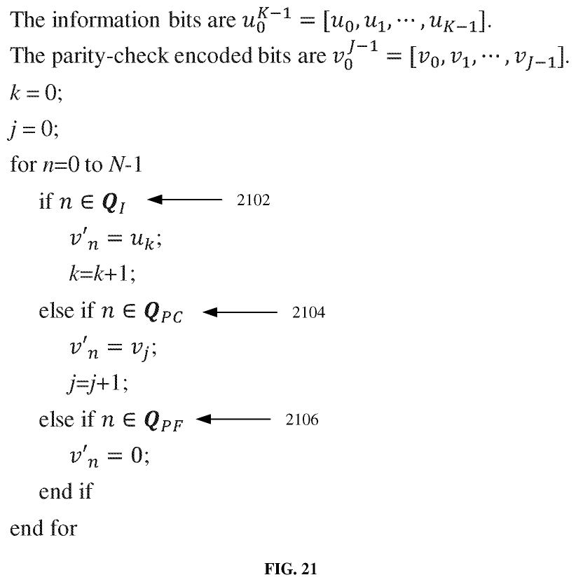

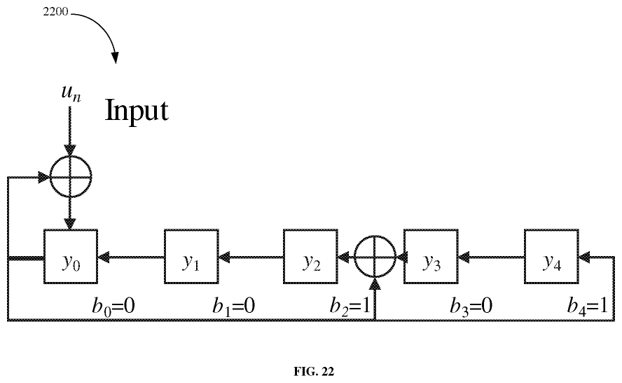

In another example, where there are information bits, pre-frozen bits, and PC bits, the encoding may be expressed in the pseudocode shown in FIG. 21.

In the example pseudocode of FIG. 21, the information bits stored in the vector

$${u}_{0}^{K - 1} ,$$

the PC bits stored in the vector

$${v}_{0}^{J - 1}$$

and frozen pits are assigned to bit positions of the vector v′ (where each bit position corresponds to a subchannel). At line 2102, it is determined whether a given n-th bit position belongs to the information set Q_{I}; if so, then the current information bit is assigned to bit position v′ₙ and the index of information bits is advanced by one. At line 2104, it is determined whether a given n-th bit position belongs to the PC set Q_{PC}; if so, then the current PC bit is assigned to bit position v′ₙ and the index of PC bits is advanced by one. At line 2106, it is determined whether a given n-th bit position belongs to the pre-freezing set Q_{PF} (as previously noted, the pre-freezing set may be frozen bits that are not converted to PC bits); if so, then the frozen bit value (e.g., bit value 0) is assigned to bit position v′ₙ. The pseudocode generates the vector v′ in which all information bits and PC bits have been mapped to the appropriate bit positions, and frozen bits have been assigned to frozen bit positions. Then polar encoding may be performed using a polar encoder matrix G_{N}.

The output after encoding d=[d₀ d₁ d₂ . . . d_{N-1}] is obtained by d=v′G_{N}. The encoding is performed in GF(2).

Some embodiments of the present disclosure relate to shift register configurations including polynomial selection.

The polynomial of a set of shift registers can unambiguously define the interconnections, or the wires that are connected to the registers, once the above parameters about shift register design are determined.

The polynomial can be defined by either a binary vector or a decimal number. For example, B_{PC}=b_{L} . . . b₀ is the binary representation of the integer β, where b_{L} is the MSB and b₀ is the LSB. If bₗ=0, it means the l-th register is not connected to any registers aside from its adjacent registers (i.e., the (l−1)-th register and the (l+1)-th register). For example, if b₃=0, this means that the y₃ register is only connected to the adjacent y₂ register and y₁ register, and is not connected to any other register. If bₗ=1, it means the l-th register is connected to at least one additional register aside from its adjacent registers, or the input or the output. For example, if b₃=1, this means that the y₃ register is connected to the adjacent y₂ register and y₁ register, and additionally is connected to at least one additional register (such as y₄ register or y₀ register) that is not adjacent to the y₃ register. The connection can be either incoming or outgoing depending on the rest configuration.

FIG. 22 illustrates an example shift register 2200, which may be used to implement a cyclic shift operation on an array of five elements y₀ to y₄. The shift register 2200 has a shift direction from highest-to-lowest index and is a cyclic shift register. In this example, the bit value of the element y₂ is based on a combination of two other elements, in this case y₂=y₃⊕y₀. In the shift register implementation shown in FIG. 22, this combination may be implemented using a feedback interconnection. The connection between lowest and highest index elements may also be considered an interconnection (as it is a connection between non-adjacent elements of the shift register 2200). The manner in which the bit values are combined, which may be implemented using interconnections of the shift register 2200, may be defined using a polynomial, which may be represented using a binary vector.

For example, the connections shown in FIG. 22 can be represented by B_{PC}=b₄ . . . b₀=10100, and its decimal representation is bin2dec (10100)=20.

The PC polynomial β can be given by a table depending on the rate matching output sequence length E and the information block length K, in the following form.

Example Table 1 below is not intended to be limiting. This example table illustrates how a polynomial that defines how bit values of different elements are combined to generate the PC bits, based on the rate matching output sequence length and based on the information block length. However, it should be understood that other ways of determining the polynomial may be used. The polynomial may be based on the rate matching output sequence length and based on the information block length, for example the polynomial may be determined by referencing the rate matching output sequence length and the information block length in a lookup table; the polynomial may be a function of the rate matching output sequence length and the information block length; the polynomial may be computed using a formula based on the rate matching output sequence length and the information block length; the polynomial may be defined by the rate matching output sequence length and the information block length; among other possibilities.

TABLE 1

| | | | |
|---|---|---|---|
| E\K | Kₘᵢₙ | . . . | Kₘₐₓ |
| Eₘᵢₙ | β_{1,1} | . . . | B_{1,x} |
| . . . | . . . | . . . | . . . |
| Eₘₐₓ | β_{y,1} | . . . | β_{x,y} |

The PC polynomial can be given by a piecewise function, i.e., β=func(N, E, K) or β=func(E, K), in which the input parameters may include the rate matching output sequence length E and the information block length K, and even the mother code length N. For example, β=52 when E₀≤32 and K≤11, and β=0 otherwise.

All of the above features are relatively independent, and thus can be freely combined to achieve the best performance.

For example, combinations can be found within {clockwise, or counter-clockwise}×{feedforward, feedback, or both feedforward and feedback}×{out from the registers, or into the registers}×{bit input position}×{bit output positions}×{whether to output information bits}, which contains up to at least 2×3×2×2×2=48 configurations. All of these configurations share the common benefits of good performance and simple description.

An example coding procedure may be expressed in the form of pseudocodes to show the PC encoding of a particular code. The polar code has length N. The encoded bits are d₀ d₁ d₂ . . . d_{N-1}. A parameter I_{PC}=1 indicates that PC encoding is enabled.

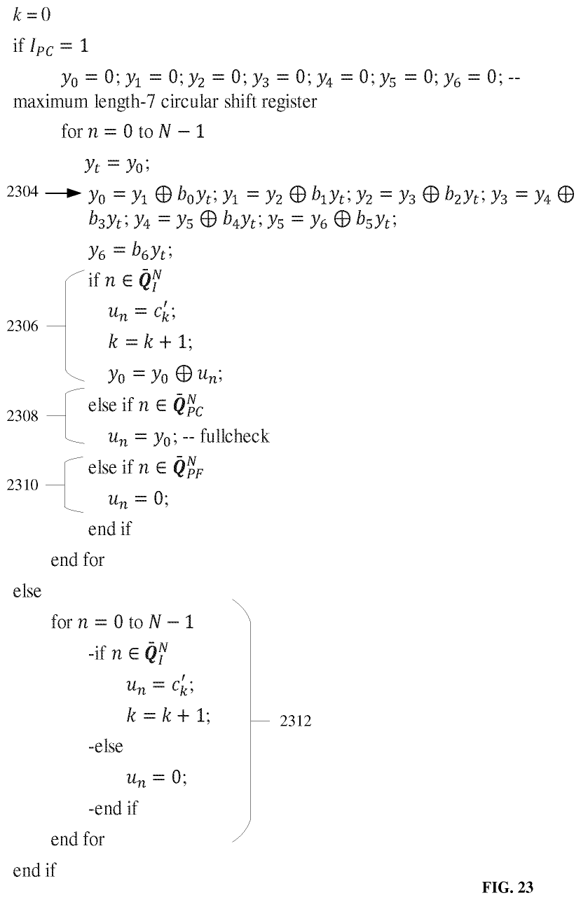

An example pseudocode is shown in FIG. 23.

The information, pre-frozen and PC bit sets are denoted respectively by

$${\overline{Q}}_{I}^{N} , {\overline{Q}}_{P F}^{N} and {\overline{Q}}_{P C}^{N} ,$$

The bit sequence to be polar encoded is denoted by u=[u₀ u₁ u₂ . . . u_{N-1}].

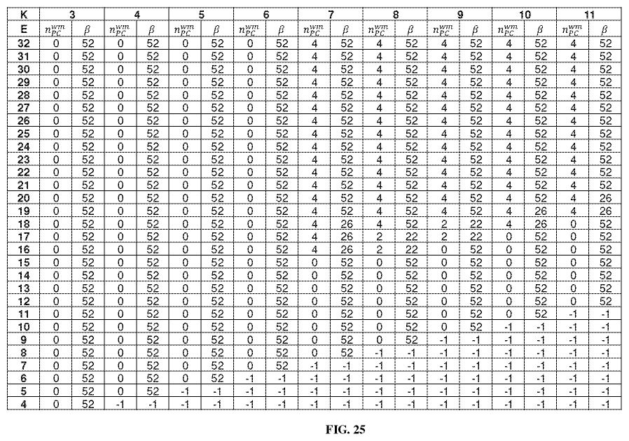

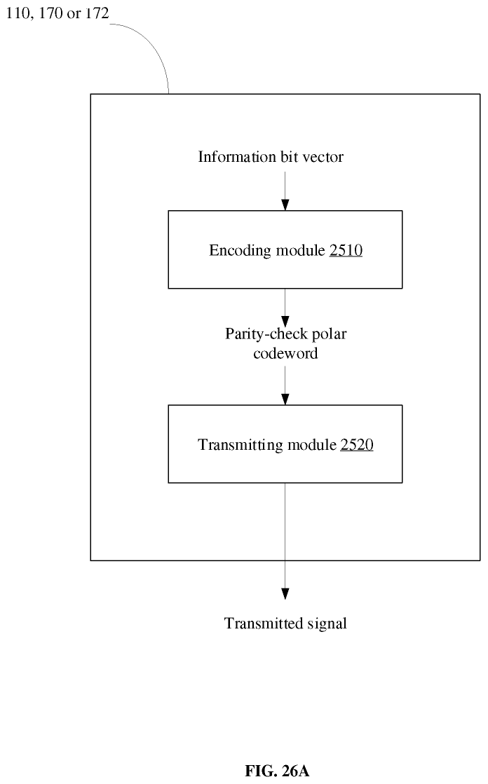

Obtain B_{PC}=b₆ . . . b₀ which is the binary representation of the integer β, where b₆ is the MSB and b₀ is the LSB. The integer β is the PC polynomial given by Table 2 (see FIG. 25): β=52 when E₀≤32 and K≤11, and β=0 otherwise.

Generate u=[u₀ u₁ u₂ . . . u_{N-1}] according to the pseudocode in FIG. 23.

In this example pseudocode, the information bits are stored in a vector

$${c}_{0}^{K - 1} .$$

The pseudocode generates the vector u that is to be polar encoded. The pseudocode at line 2302 determines whether PC encoding is enabled (e.g., whether I_{PC}=1). If PC encoding is enabled, then a PC encoding procedure as described herein may be used and the vector u may be referred to as a PC encoded vector. If PC encoding is not enabled, then the section 2312 may be used to assign information bits or frozen bits to u without using PC encoding.

If PC encoding is enabled, a cyclic shift operation may be used to generate PC bits. This example pseudocode uses a cyclic shift operation (which may be implemented using a cyclic shift register or logic or both) on an array of elements of length seven, with elements y₀ to y₆. In general, a shift operation that operates on an array having a prime number or odd number of elements may have better performance than arrays of other lengths. Although an array of seven elements is shown in the pseudocode, this is only exemplary. The shift direction of the cyclic shift operation and the manner in which bit values are combined are represented at line 2304. In particular, the i-th element yᵢ is set to be the value of the upstream adjacent element (where upstream refers to the adjacent element that is opposite to the shift direction) XOR with the i-th element of B_{PC} multiplied with yₜ (which is a temporary storage for the value of y₀ when the shift direction is MSB to LSB; or is a temporary storage for the value of yₘₐₓ when the shift direction is LSB to MSB and yₘₐₓ is the highest index element). Thus, if the shift direction is from MSB to LSB, then the i-th element yᵢ may be set to be yᵢ=yᵢ₊₁⊕bᵢyₜ; if there is no element yᵢ₊₁ (i.e., yᵢ is the highest index element of the shift register) then yᵢ may be set to be yᵢ=bᵢyₜ. If the shift direction is from LSB to MSB, then the i-th element yᵢ may be set to be yᵢ=yᵢ₋₁⊕bᵢyₜ; if there is no element yᵢ₋₁ (i.e., yᵢ is the lowest index element of the shift register) then yᵢ may be set to be yᵢ=bᵢyₜ. This may be implemented in logic, such as at line 2304, or may be implemented by connecting elements of a shift register according to the interconnections defined by the polynomial represented by B_{PC}. Some combination of logic and hardware implementation may also be used.

At section 2306, it is determined whether a given n-th bit position uₙ belongs to the information set

$${\overline{Q}}_{I}^{N} ;$$

if so, then the current information bit c′ₖ is assigned to the bit position uₙ, the bit value is inputted to the cyclic shift operation, as represented by the expression y₀=y₀⊕uₙ (e.g., stored or written in to the input of the shift register, if a shift register is used to implement the cyclic shift operation) and the index of information bits is advanced by one (e.g., k=k+1). At section 2308, it is determined whether a given n-th bit position uₙ belongs to the PC set

$${\overline{Q}}_{P C}^{N} ;$$

if so, then the current PC bit is outputted from the cyclic shift operation and assigned to the position uₙ, as represented by the expression uₙ=y₀ (e.g., outputted or read from the output of the shift register, if a shift register is used to implement the cyclic shift operation). In the case of a fullcheck configuration, all frozen bit positions (except for pre-freezing bit positions) may be used for PC bits. At section 2310, it is determined whether a given n-th bit position uₙ belongs to the pre-freezing set

$${\overline{Q}}_{P F}^{N} ;$$

if so, then the frozen bit value (e.g., bit value 0) is assigned to the bit position uₙ. The pseudocode generates the vector u in which information bits, PC bits and frozen bits have been assigned to the appropriate bit positions. Then polar encoding may be performed using a polar encoder matrix G_{N}.

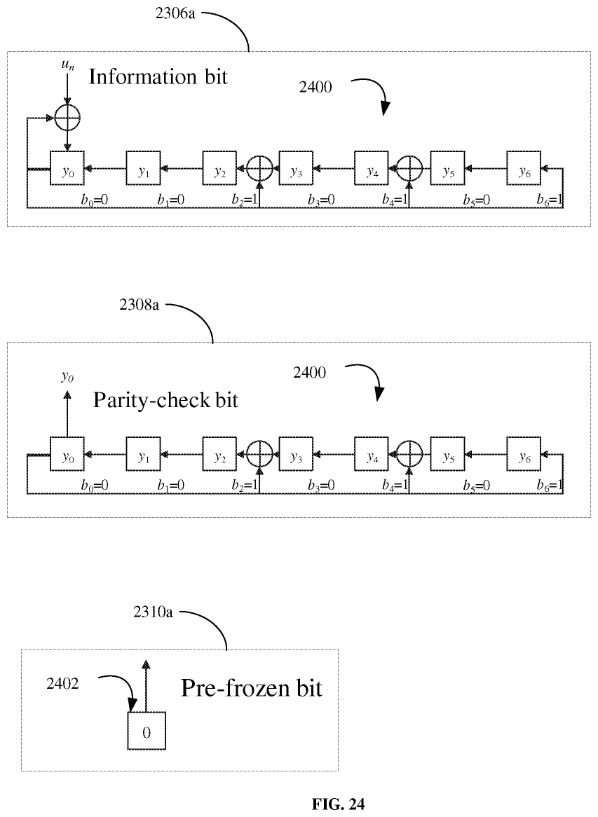

An example of the above PC encoding can be represented by FIG. 24.

FIG. 24 illustrates a cyclic shift register 2400 of length seven, having elements y₀ to y₆ and interconnections represented by B_{PC}=b₆ . . . b₀, which may be used to implement the cyclic shift operation used in the pseudocode of FIG. 23 as previously discussed. It should be understood that although FIG. 24 illustrates two instances of the cyclic shift register 2400, this is intended to show how the same cyclic shift register 2400 is used in the case of an information bit being inputted and in the case of a PC bit being outputted. That is, FIG. 24 should not be interpreted as there being different shift registers used for the information bits and the PC bits. FIG. 24 illustrates an example operation 2306a in which the bit value of an information bit is inputted to the shift register 2400 and is also assigned to the position uₙ, for example as previously discussed with respect to section 2306 of the pseudocode of FIG. 23. FIG. 24 also illustrates an example operation 2308a in which the bit value of a PC bit is outputted from the shift register 2400, for example as previously discussed with respect to section 2308 of the pseudocode of FIG. 23. Finally, FIG. 24 illustrates an example operation 2310a in which a fixed frozen bit value 0 is assigned to a pre-frozen bit position, for example as previously discussed with respect to section 2310 of the pseudocode of FIG. 23.

The output after encoding d=[d₀ d₁ d₂ . . . d_{N-1}] is obtained by d=uG_{N}. The encoding is performed in GF(2).

FIG. 25 shows Table 2 containing example polar parameters for parity check bits, as previously discussed.

The above descriptions mainly determine the following PC-polar related parameters:

Which configuration of PC encoding is selected, the configuration may be used to specify {clockwise, or counter-clockwise}, and/or {feedforward, feedback, or both feedforward and feedback}, and/or {out from the registers, or into the registers}, and/or {bit input position}, and/or {bit output positions}, and/or {whether to output information bits}, etc.

These parameters can either be pre-defined in standard specifications, or signaled using Radio Resource Control (RRC) messages or UCI control information.

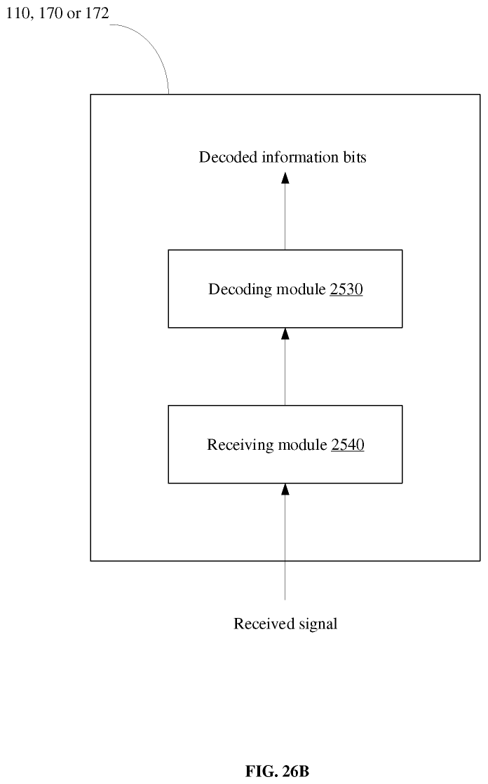

Reference is now made to FIGS. 26A-B. FIG. 26A illustrates an example device, such as the ED 110, T-TRP 170 and/or NT-TRP 172 previously described, including an encoding unit or module 2510 (generally referred to hereinafter as the encoding module 2510). The encoding module 2510 may be provided in addition to any one or more of the units or modules shown in FIG. 4, for example, however for simplicity not all units or modules of the device are shown in FIG. 26A. In some examples, the encoding module 2510 may be provided as a submodule of any of the units or modules previously described. Also shown in FIG. 26A is a transmitting unit or module 2520 (generally referred to hereinafter as the transmitting module 2520), which has been previously discussed with respect to FIG. 4.

The encoding module 2510 and/or transmitting module 2520 may be implemented as software, hardware or a combination of software and hardware. For example, the encoding module 2510 and/or transmitting module 2520 may be a circuit such as an integrated circuit. Examples of an integrated circuit includes a programmed FPGA, a GPU, or an ASIC. For instance, the encoding module 2510 and/or transmitting module 2520 may be at least partly implemented as logic, such as a logical function performed by a circuit, by a portion of an integrated circuit, or by software instructions executed by a processor, among other possibilities.

The encoding module 2510 and transmitting module 2520 may be used by a transmitting device to encode information bits of a bit vector into a PC polar codeword (e.g., using any of the examples of the present disclosure), and transmitting the PC polar codeword as a wireless communication signal over a communication channel.

In particular, the encoding module 2510 may encode the information bit vector into a PC polar codeword in which PC encoding is used on a subblock basis rather than on a codeword basis. Although not shown in FIG. 26A, the encoding module 2510 may include a PC-encoding submodule and a polar encoding submodule. The PC-encoding submodule may be used to generate a PC-encoded vector from the information bits of the information bit vector. As discussed elsewhere in this disclosure, a cyclic shift operation (which may be implemented using various hardware and/or software techniques, such as using a set of cyclically-connected shift registers (also referred to as a cyclic shift register), using a hash function, using a lookup table, using logic, etc.) may be used by the PC-encoding submodule to generate PC bits from information bits. The generated PC bits may be assigned to less reliable bit positions (e.g., frozen bit positions) of the PC-encoded vector while the information bits may be assigned to more reliable bit positions (e.g., information bit positions) of the PC-encoded vector. The polar encoding submodule may then be used to generate the PC polar codeword from the PC-encoded vector.

FIG. 26B illustrates another example device, which may be an instance of the ED 110, T-TRP 170 and/or NT-TRP 172 previously described, including a decoding unit or module 2530 (generally referred to hereinafter as the decoding module 2530). The decoding module 2530 may be provided in addition to any one or more of the units or modules shown in FIG. 4, for example, however for simplicity not all units or modules of the device are shown in FIG. 26B. In some examples, the decoding module 2530 may be provided as a submodule of any of the units or modules previously described. Also shown in FIG. 26B is a receiving unit or module 2540 (generally referred to hereinafter as the receiving module 2540), which has been previously discussed with respect to FIG. 4.

The decoding module 2530 and/or receiving module 2540 may be implemented as software, hardware or a combination of software and hardware. For example, the decoding module 2530 and/or receiving module 2540 may be a circuit such as an integrated circuit. Examples of an integrated circuit includes a programmed FPGA, a GPU, or an ASIC. For instance, the decoding module 2530 and/or receiving module 2540 may be at least partly implemented as logic, such as a logical function performed by a circuit, by a portion of an integrated circuit, or by software instructions executed by a processor, among other possibilities.

The decoding module 2530 and receiving module 2540 may be used by a receiving device to receive a wireless communication signal that contains at least one subblock of a PC polar codeword and to decode the subblock to recover the information bits encoded in the subblock. In particular, the decoding module 2530 may decode a subblock of a PC polar codeword using PC bits of that subblock, without requiring other subblocks of the PC polar codeword.

It should be understood that FIGS. 26A and 26B may represent the same device. That is, a single device may have the encoding module 2510, transmitting module 2520, decoding module 2530 and receiving module 2540. The device may perform encoding and transmitting when the device is in the role of a transmitting device, and may perform receiving and decoding operations when the device is in the role of a receiving device. In some examples, the encoding module 2510 and decoding module 2530 may be implemented together as an encoder/decoder module and the transmitting module 2520 and receiving module 2540 may be implemented together as a transceiver module.

In various examples, the present disclosure describes methods for generating a PC polar codeword using a cyclic shift operation on an array of elements. Each element in the array is used to store a respective bit value. The cyclic shift operation causes the bit value stored in each element to be shifted (or written) to a next downstream element (and the bit value of the most downstream element is shifted back to the most upstream element, thus forming a cyclic shift). As discussed in this disclosure, a cyclic shift operation may be implemented using software (e.g., logic), hardware (e.g., cyclic shift register) or a combination of software and hardware.

In a hardware-based implementation (e.g., using a cyclic shift register), each element may be a memory element for storing a single bit value (e.g., each element may be a storage element of the cyclic shift register, such as a flip-flop). Each element may have a connection (e.g., wire connection) to the next downstream element, and the most downstream element may have a connection (e.g., wire connection) to the most upstream element. In a software-based implementation, there may not be a physical connection between elements of the array, and the elements need not be stored adjacent to each other in physical memory (although there may be advantages, such as reduced latency, in storing elements adjacent to each other in physical memory, even in a logic-based implementation). A combination of hardware and software may be used to implement cyclic shift operations. For example, a cyclic shift register may be used in which bit values of multiple elements can be combined into one element using a logical operation (e.g., using a binary vector representation of a polynomial in an XOR operation) rather than using wire interconnections.

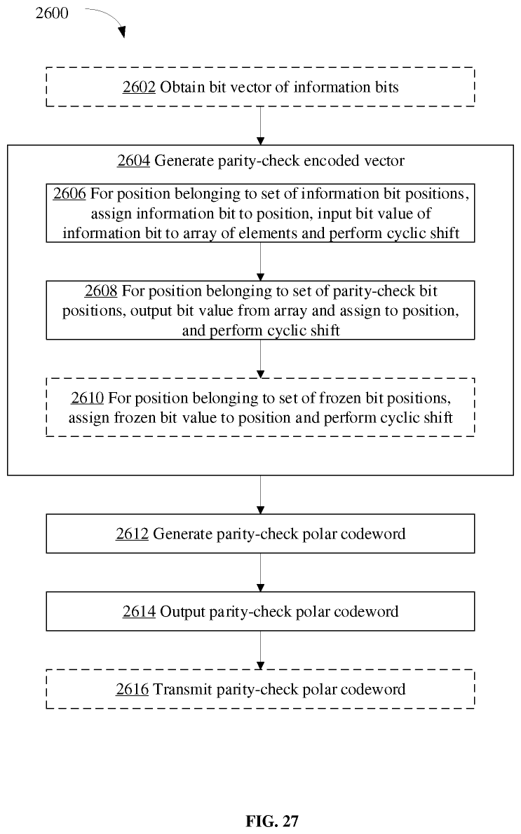

FIG. 27 is a flowchart illustrating an example method 2600 for generating a PC polar codeword. The method 2600 may be implemented by a processor executing instructions of the encoding module 2510 (and optionally the transmitting module 2520), for example. The method 2600 may be used to carry out various examples of PC-polar encoding described herein. In some examples, the method 2500 may be carried out by an apparatus that is acting as a transmitting device.

Optionally, at an operation 2602, a bit vector of information bits to be encoded may be obtained. For example, the bit vector of information bits may represent data (which may be generated by the apparatus or may be received by the apparatus) that is to be transmitted to an intended receiving device.

At an operation 2604, a PC encoded vector is generated based on the bit vector of information bits to be encoded. The PC encoded vector is generated based on a set of information bit positions (also referred to as the information set) and a set of PC bit positions (also referred to as the PC set). Optionally, the PC encoded vector may also be generated based on a set of frozen bit positions (also referred to as the frozen set). The information set, PC set and optional frozen set may be predefined (e.g., in accordance with a standard) and are used to determine what type of bit is carried in each bit position of the PC encoded vector. As a detailed operation of the operation 2604, an operation 2606, an operation 2608 and an optional operation 2610 may be performed.

In examples disclosed herein, generating the PC encoded vector includes generating PC bits using cyclic shift operations on an array of elements. Some discussion of the cyclic shift operation is now provided with reference to some of the examples discussed previously.

In some examples, the array of elements may be initialized (or reset) at the start of the method 2600. For example, the array of elements may be initialized or reset to carry a fixed bit value (e.g., all elements may be initialized or reset to carry a bit value of zero) or to carry a predefined set of bit values (e.g., based on a radio network temporary identifier (RNTI), such as a UE-specific RNTI (e.g., RNTI of the intended receiving device), a common RNTI or a cell-specific RNTI, etc.).

In some examples, the cyclic shift operation may be performed on an array of elements having five or more elements. In some examples, the array of elements may have a prime number of elements or an odd number of elements equal to or greater than five. It has been found that using a prime number or odd number of elements for generating the PC bits generally results in better performance. Some examples described herein use a length-7 array of elements (e.g., as shown in FIG. 24), however this is not intended to be limiting.

In some examples, the cyclic shift operation is performed on an array of elements in which at least one element is based on a combination of two or more other elements in the array. There may be multiple such combinations, for increased complexity in how PC bits are generated. For example, the bit value of at least one element may be an XOR of bit values of two or more other elements in the array. In examples where the cyclic shift operation is implemented using a cyclic shift register, the combination of elements may be implemented using interconnections between elements of the cyclic shift register, for example as shown in the examples of FIGS. 13 and 15A-18. As shown in FIG. 13, the interconnections between elements of the cyclic shift register may be implemented in logic (e.g., using XOR operations instead of using wire interconnections).

A combination of elements may be a feedback combination in which the two or more other elements that are combined include one other element that is downstream of the at least one element in the shift direction. For example, if the shift direction is in the direction of increasing index, a feedback combination may be represented by the expression yᵢ=yᵢ₊₁⊕yᵢ₋₁, in which the bit value of the element yᵢ is a combination (in this case XOR) of the downstream element yᵢ₊₁ and the upstream element yᵢ₋₁. Such a feedback combination may be implemented using logic (e.g., by performing a XOR operation in logic), or if using a cyclic shift register a feedback combination may be implemented using a directional interconnection that is opposite in direction to the shift direction.

A combination of elements may additionally or alternatively be a feedforward combination in which the two or more other elements that are combined include only elements that are upstream of the at least one element in the shift direction. For example, if the shift direction is in the direction of increasing index, a feedforward combination may be represented by the expression yᵢ=yᵢ₋₂⊕yᵢ₋₁, in which the bit value of the element yᵢ is a combination (in this case XOR) of the upstream elements yᵢ₋₂ and yᵢ₋₁. Such a feedforward combination may be implemented using logic (e.g., by performing a XOR operation in logic), or if using a cyclic shift register a feedforward combination may be implemented using a directional interconnection that is in the same direction as the shift direction.

FIGS. 15A-B illustrate examples of feedforward interconnections for implementing feedforward combination of elements in a cyclic shift register, and FIGS. 15C-D illustrate examples of feedback interconnections for implementing feedback combination of elements in a cyclic shift register. Additionally, both feedforward and feedback combinations may be used, such as illustrated by the use of both feedforward and feedback interconnections in the example shift registers of FIGS. 15E-G.

In some examples, the combination of elements may be represented by a polynomial. A binary vector representation of the polynomial may be used to implement the combination of elements, for example as illustrated at line 2304 in the pseudocode of FIG. 23. The polynomial may be based on a given rate matching output sequence length and a given information block length; for example, the polynomial may be defined by the given rate matching output sequence length and the given information block length, the given rate matching output sequence length and the given information block length may be used to reference a lookup table to determine the polynomial, the polynomial may be a function of the given rate matching output sequence length and the given information block length, the polynomial may be computed using the given rate matching output sequence length and the given information block length, etc.

In some examples, the cyclic shift operation may be performed in a shift direction from a highest index element in the array of elements to a lowest index element in the array of elements. For example, the highest index element may correspond to a most significant bit and the lowest index element may corresponding to a least significant bit. In a cyclic shift register implementation, this may be implemented by connecting adjacent elements in the array using directional connections in the direction of low-to-high index.

In some examples, the cyclic shift operation may be performed in a shift direction from a lowest index element in the array of elements to a highest index element in the array of elements (e.g., from the least significant bit to the most significant bit). In a cyclic shift register implementation, this may be implemented by connecting adjacent elements in the array using directional connections in the direction of high-to-low index.

FIGS. 14A-B illustrate examples of cyclic shift registers having elements connected in a lowest index to highest index direction, and FIGS. 14C-D illustrate examples of cyclic shift registers having elements connected in a highest index to lowest index direction.

Returning to FIG. 27, detailed operation of the operation 2604 may include performing the operation 2606, the operation 2608 and the optional operation 2610.

The operation 2606 is performed for a first position in the PC encoded vector belonging to the set of information bit positions. An information bit from the bit vector is assigned to the first position, a bit value of the information bit is inputted to the array of elements and the array of elements is cyclic shifted by one in the shift direction.

The element at which the bit value of the information bit is inputted to the array of elements may be the lowest index element in the array, the highest index element in the array, or some element other than the highest indexed or lowest indexed element. FIG. 16A illustrates an example cyclic shift register implementation in which the input to the array of elements is at the lowest index element; FIG. 16B illustrates an example cyclic shift register implementation in which the input to the array of elements is at the highest index element; and FIG. 16C illustrates an example cyclic shift register implementation in which the input to the array of elements is at an element other than the highest or lowest index element.

The operation 2608 is performed for a second position in the PC encoded vector belonging to the set of one or more PC bit positions. A bit value of a PC bit is outputted from the array of elements and assigned to the second position, and the array of elements is cyclic shifted by one in the shift direction.

A PC bit that is generated from information bits may be carried in bit positions after the first information bit position. Prior to the first information bit, the array of elements may carry fixed bit values (e.g., all zero bit values) or a predefined set of bit values (e.g., the array of elements may be initialized to carry bit values based on a RNTI). If a bit position belonging to the set of PC bit positions is before the first information bit position, the bit value that is outputted from the array of elements and assigned to that position may thus be a fixed bit value or a bit value from the predefined set of bit values.

The element at which the bit value of the PC bit is outputted from the array of elements may be the highest index element in the array, the lowest index element in the array, or some element other than the highest indexed or lowest indexed element. FIG. 16D illustrates an example cyclic shift register implementation in which the output from the array of elements is at the highest index element; FIG. 16E illustrates an example cyclic shift register implementation in which the output from the array of elements is at the lowest index element; and FIG. 16F illustrates an example cyclic shift register implementation in which the output from the array of elements is at an element other than the highest or lowest index element.

The optional operation 2610 may be performed for a third position in the PC encoded vector belonging to the set of frozen bit positions. A frozen bit value may be assigned to the third position, and the array of elements may be cyclic shifted by one in the shift direction. The frozen bit value may be a fixed bit value (e.g., bit value of 0) or a value from a defined set of values (e.g., based on a RNTI), for example.

It may be noted that the bit positions of the PC encoded vector may be filled bit-by-bit, for example by advancing the index of the PC encoded vector one at a time and determining (e.g., based on the information set and PC set, and optionally the frozen set) whether the bit position at the current index should carry an information bit or a PC bit (or optionally a frozen bit). If the current bit position should carry an information bit, that bit position may be assigned an information bit in the bit vector that has not yet been assigned; or if the current bit position should carry a PC bit, that bit position may be assigned the next PC bit (e.g., outputted from the cyclic shift operation, such as read out from a shift register). If the current bit position should carry a frozen bit, that bit position may be assigned a frozen bit value.

Thus, the operations 2606, 2608 and optionally 2610 may be performed together to assign the appropriate bit to each bit position of the PC encoded vector.

In some examples, the resulting PC encoded vector may contain only PC bits that are not a copy of a previous information bit. That is, all the bits in the PC encoded vector may be outputted from the array of elements and not a direct copy of a prior information bit previously inputted to the array of elements. For example, the bit value of at least one element in the array of elements may be a combination of bit values of other elements, such that the resulting bit element at the output of the array of elements is not a direct copy of a prior information bit.

After all bit positions of the PC encoded vector have been filled with appropriate bit values, the complete PC encoded vector may be provided as input to a polar encoder.

At an operation 2612, the PC polar codeword is generated by applying a polar code to the PC encoded vector. For example, a polar encoding matrix may be applied to the PC encoded vector.

At an operation 2614, the PC polar codeword is outputted. For example, the PC polar codeword may be outputted by the encoding module.

Optionally, at an operation 2616, the PC polar codeword may be transmitted. For example, a transmitting module of the transmitting device may transmit the PC polar codeword as a wireless communication signal over a communication channel to an intended receiving device.

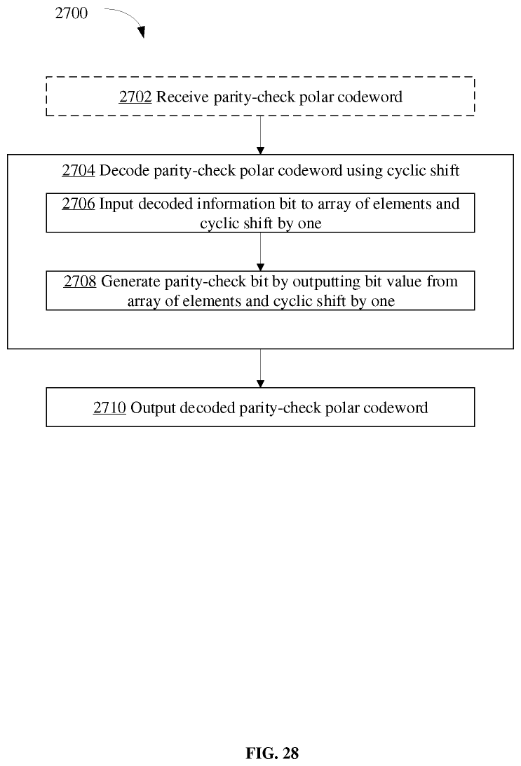

FIG. 28 is a flowchart illustrating an example method 2700 for decoding a PC polar codeword. The method 2700 may be implemented by a processor executing instructions of the decoding module 2530 (and optionally the receiving module 2540), for example. The method 2700 may be used to decode various examples of PC-polar codewords described herein. In some examples, the method 2700 may be carried out by an apparatus that is a receiving device.

Optionally, at an operation 2702, a PC polar codeword is received. For example, a receiving module may receive a wireless communication signal over a communication channel, where the PC polar codeword is carried by the signal.

At an operation 2704, the PC polar codeword is decoded using a cyclic shift operation. Decoding the PC polar codeword includes generating PC bits during the successive cancellation (SC) or successive cancellation list (SCL) decoding, in particular the PC bits are generated using the same process by which PC bits were generated during encoding. Thus, the example cyclic shift operations discussed previously may be similarly performed at the operation 2704 and need not be repeated here. As a detailed operation of the operation 2704, an operation 2706 and an operation 2708 may be performed.

At the operation 2706, a bit value of each decoded information bit is inputted to an array of elements and the array of elements is cyclic shifted by one in a shift direction.

At the operation 2708, one or more PC bits are generated by, for each PC bit, outputting a bit value of the PC bit from the array of elements and cyclic shifting the array of elements by one in the shift direction.

As previously discussed, the cyclic shift operation may be performed on an array of elements having a length of five or greater. At least one element in the array of elements may have a bit value based on a combination of two or more other elements in the array of elements. The cyclic shift operation and array of elements may be implemented using a cyclic shift register. The cyclic shift register may include an interconnection to implement the combination of the two or more other elements.

Following the operation 2704, at an operation 2210, the decoded PC polar codeword is outputted.

In examples disclosed herein, a PC polar codeword may be generated in which PC encoding includes the use of a cyclic shift operation for generating PC bits. The cyclic shift operation may be performed on an array of elements of length five or greater (e.g., using a cyclic shift register of length five or greater) and/or bit values of multiple elements may be combined into another element in the array (e.g., using interconnections in a cyclic shift register). The use of a longer array of elements and/or combination (e.g., XOR) of bit values in the array of elements may enable greater flexibility and variation in how PC bits are generated from information bits. Using examples of the present disclosure, longer PC polar codewords may be generated that exhibit more stable performance (e.g., lower error rate) compared to other approaches that use a cyclic shift register of length five or shorter and/or that do not use combination of bit values for generating PC bits. For example, the use of a longer array and/or combination of bit values in generating PC bits may enable generation of PC polar codewords having longer length, better code weight and larger minimum distance between codewords, among other possible technical advantages.

The present disclosure encompasses various embodiments, including not only method embodiments, but also other embodiments such as apparatus embodiments and embodiments related to non-transitory computer readable storage media. Embodiments may incorporate, individually or in combinations, the features disclosed herein.

Although this disclosure refers to illustrative embodiments, this is not intended to be construed in a limiting sense. Various modifications and combinations of the illustrative embodiments, as well as other embodiments of the disclosure, will be apparent to persons skilled in the art upon reference to the description.

Features disclosed herein in the context of any particular embodiments may also or instead be implemented in other embodiments. Method embodiments, for example, may also or instead be implemented in apparatus, system, and/or computer program product embodiments. In addition, although embodiments are described primarily in the context of methods and apparatus, other implementations are also contemplated, as instructions stored on one or more non-transitory computer-readable media, for example. Such media could store programming or instructions to perform any of various methods consistent with the present disclosure.

It should be understood that examples of the present disclosure may be embodied as a method, an apparatus, a non-transitory computer readable medium, a processing module, a chipset, a system chip or a computer program, among others. An apparatus may include a transmitting module configured to carry out transmitting steps described above and a receiving module configured to carry out receiving steps described above. An apparatus may include a processing module, processor or processing unit configured to control or cause the apparatus to carry out examples disclosed herein.

Although the present disclosure describes methods and processes with steps in a certain order, one or more steps of the methods and processes may be omitted or altered as appropriate. One or more steps may take place in an order other than that in which they are described, as appropriate.

Although the present disclosure is described, at least in part, in terms of methods, a person of ordinary skill in the art will understand that the present disclosure is also directed to the various components for performing at least some of the aspects and features of the described methods, be it by way of hardware components, software or any combination of the two. Accordingly, the technical solution of the present disclosure may be embodied in the form of a software product. A suitable software product may be stored in a pre-recorded storage device or other similar non-volatile or non-transitory computer readable medium, including DVDs, CD-ROMs, USB flash disk, a removable hard disk, or other storage media, for example. The software product includes instructions tangibly stored thereon that enable a processing device (e.g., a personal computer, a server, or a network device) to execute examples of the methods disclosed herein. The machine-executable instructions may be in the form of code sequences, configuration information, or other data, which, when executed, cause a machine (e.g., a processor or other processing device) to perform steps in a method according to examples of the present disclosure.

The present disclosure may be embodied in other specific forms without departing from the subject matter of the claims. The described example embodiments are to be considered in all respects as being only illustrative and not restrictive. Selected features from one or more of the above-described embodiments may be combined to create alternative embodiments not explicitly described, features suitable for such combinations being understood within the scope of this disclosure.

All values and sub-ranges within disclosed ranges are also disclosed. Also, although the systems, devices and processes disclosed and shown herein may comprise a specific number of elements/components, the systems, devices and assemblies could be modified to include additional or fewer of such elements/components. For example, although any of the elements/components disclosed may be referenced as being singular, the embodiments disclosed herein could be modified to include a plurality of such elements/components. The subject matter described herein intends to cover and embrace all suitable changes in technology. Acronyms, Abbreviations, and Initialisms

| Full Name | Acronym/Abbreviation/Initialism |
|---|---|
| Long Term Evolution | LTE |
| New Radio | NR |
| Forward error correction | FEC |
| Multiple Access | MA |
| Quality of Service | Qos |
| low-density parity check codes | LDPC |
| cyclic redundancy check | CRC |
| Parity check | PC |
| ultra-reliable low latency | uRLLC |
| communications | |
| Enhanced mobile broadband | eMBB |
| massive Machine Type | mMTC |
| Communications | |
| non-terrestrial networks | NTN |
| Internet of Things | IOT |
| Bit Error Rate | BER |
| Block Error Rate | BLER |
| Packet Error Rate | PER |
| Spectral Efficiency | SE |
| Hybrid automatic repeat request | HARQ |
| Incremental-redundancy HARQ | IR-HARQ |
| Channel Quality Indicator | CQI |
| Modulation Coding Scheme | MCS |
| gNodeB or 5G base station | gNB |
| user equipment | UE |
| Radio Resource Control | RRC |
| Radio Network Temporary | RNTI |
| Identifier | |
| Uplink Control Information | UCI |
| Downlink Control Information | DCI |
| Physical Broadcast Channel | PBCH |
| Half-radio frame bit | HRF |
| Synchronization Signal Block | SSB |
| unequal error protection | UEP |
| variable node | VN |
| check node | CN |
| Log-likelihood ratio | LLR |
| Successive cancellation | SC |
| Successive cancellation list | SCL |
| CRC-aided successive | CA-SCL |
| cancellation list | |
| Parity-check successive | PC-SCL |
| cancellation list | |

What is claimed is:

1. A method, comprising:
generating a parity-check encoded vector based on a set of information bit positions and a set of one or more parity-check bit positions;
generating a parity-check polar codeword by applying a polar code to the parity-check encoded vector; and
outputting the parity-check polar codeword, wherein:
for a first position in the parity-check encoded vector belonging to the set of information bit positions: an information bit from a bit vector of information bits is assigned to the first position, a bit value of the information bit is inputted to an array of elements, and the array of elements is cyclic shifted by one in a shift direction;
for a second position in the parity-check encoded vector belonging to the set of one or more parity-check bit positions: a bit value of a parity-check bit is outputted from the array of elements and assigned to the second position, and the array of elements is cyclic shifted by one in the shift direction; and
the array of elements has five or more elements.

2. The method of claim 1, wherein at least one element in the array of elements is based on a combination of two or more other elements in the array of elements.

3. The method of claim 2, wherein the combination is a feedback combination in which the two or more other elements that are combined include one other element that is downstream of the at least one element in the shift direction.

4. The method of claim 2, wherein the combination is a feedforward combination in which the two or more other elements that are combined are other elements that are upstream of the at least one element in the shift direction.

5. The method of claim 2, wherein the cyclic shifting and the array of elements are implemented using a cyclic shift register, and wherein the cyclic shift register includes an interconnection to implement the combination of the two or more other elements.

6. The method of claim 5, wherein the interconnection is a feedforward interconnection, the feedforward interconnection being a directional interconnection that is in a same direction as the shift direction of the cyclic shift register.

7. The method of claim 5, wherein the interconnection is a feedback interconnection, the feedback interconnection being a directional interconnection that is opposite in direction to the shift direction of the cyclic shift register.

8. The method of claim 2, wherein there are one or more elements based on respective one or more combinations of other elements, and wherein the one or more combinations are implemented using a binary vector representation of a polynomial representing the one or more combinations.

9. A method, the method comprising:
decoding a parity-check polar codeword, wherein the decoding includes:
inputting a bit value of each decoded information bit of one or more decoded information bits to an array of elements, and cyclic shifting the array of elements by one in a shift direction; and
generating one or more parity-check bits by, for each parity-check bit, outputting a bit value of the parity-check bit from the array of elements and cyclic shifting the array of elements by one in the shift direction, wherein the array of elements has five or more elements; and
outputting the decoded parity-check polar codeword.

10. The method of claim 9, wherein at least one element in the array of elements is based on a combination of two or more other elements in the array of elements.

11. An apparatus comprising:
at least one processor; and
memory including instructions that, when executed by the at least one processor, cause the apparatus to:
generate a parity-check encoded vector based on a set of information bit positions and a set of one or more parity-check bit positions;
generate a parity-check polar codeword by applying a polar code to the parity-check encoded vector; and
output the parity-check polar codeword, wherein:
for a first position in the parity-check encoded vector belonging to the set of information bit positions: an information bit from a bit vector of information bits is assigned to the first position, a bit value of the information bit is inputted to an array of elements, and the array of elements is cyclic shifted by one in a shift direction;
for a second position in the parity-check encoded vector belonging to the set of one or more parity-check bit positions: a bit value of a parity-check bit is outputted from the array of elements and assigned to the second position, and the array of elements is cyclic shifted by one in the shift direction; and
the array of elements has five or more elements.

12. The apparatus of claim 11, wherein at least one element in the array of elements is based on a combination of two or more other elements in the array of elements.

13. The apparatus of claim 12, wherein the combination is a feedback combination in which the two or more other elements that are combined include one other element that is downstream of the at least one element in the shift direction.

14. The apparatus of claim 12, wherein the combination is a feedforward combination in which the two or more other elements that are combined are other elements that are upstream of the at least one element in the shift direction.

15. The apparatus of claim 12, wherein the cyclic shifting and the array of elements are implemented using a cyclic shift register, and wherein the cyclic shift register includes an interconnection to implement the combination of the two or more other elements.

16. The apparatus of claim 15, wherein the interconnection is a feedforward interconnection, the feedforward interconnection being a directional interconnection that is in a same direction as the shift direction of the cyclic shift register.

17. The apparatus of claim 15, wherein the interconnection is a feedback interconnection, the feedback interconnection being a directional interconnection that is opposite in direction to the shift direction of the cyclic shift register.

18. The apparatus of claim 12, wherein there are one or more elements based on respective one or more combinations of other elements, and wherein the one or more combinations are implemented using a binary vector representation of a polynomial representing the one or more combinations.

19. An apparatus comprising:
at least one processor; and
memory including instructions that, when executed by the at least one processor, cause the apparatus to:
decode a parity-check polar codeword, wherein the decoding includes:
inputting a bit value of each decoded information bit of one or more decided information bits to an array of elements, and cyclic shifting the array of elements by one in a shift direction; and
generating one or more parity-check bits by, for each parity-check bit, outputting a bit value of the parity-check bit from the array of elements, and cyclic shifting the array of elements by one in the shift direction, wherein the array of elements has five or more elements; and
output the decoded parity-check polar codeword.

20. The apparatus of claim 19, wherein at least one element in the array of elements is based on a combination of two or more other elements in the array of elements.
